(19) United States
(12) Patent Application Publication
(10) Pub. No.: US 2026/0311769 A1
(43) Pub. Date: Oct. 8, 2026

(54) NONVOLATILE MEMORY DEVICE AND METHOD OF OPERATING THE SAME

(71) Applicant: Samsung Electronics Co., Ltd., Suwon-si (KR)

(72) Inventors: Doohee Hwang, Suwon-si (KR); Sanghoon Kim, Suwon-si (KR); Sungwon Shin, Suwon-si (KR); Yerim Shin, Suwon-si (KR); Younsoub Im, Suwon-si (KR); Seungjae Baik, Suwon-si (KR); Jaeduk Lee, Suwon-si (KR)

(21) Appl. No.: 19/451,809

(22) Filed: Jan. 16, 2026

(30) Foreign Application Priority Data
Feb. 18, 2025 (KR) 10-2025-0020691

(51) Int. Cl. G11C 16/14; G11C 16/04; G11C 16/08

(52) U.S. Cl. CPC G11C 16/14; G11C 16/0483; G11C 16/08

(57) ABSTRACT

A method of operating a nonvolatile memory device includes sequentially performing an erase operation, a back-tunneling electron-injection operation, and a program operation. The erase operation is performed to release electrons in charge storage regions of a plurality of memory cells of the nonvolatile memory device. The back-tunneling electron-injection operation is performed to inject electrons into a spacer region between a charge storage region corresponding to a target wordline and a charge storage region corresponding to a neighboring wordline adjacent to the target wordline by applying a back-tunneling voltage to the target wordline and a boosting voltage higher than the back-tunneling voltage to the neighboring wordline. The program operation is performed to inject electrons into the charge storage region corresponding to the target wordline.

### CROSS-REFERENCE TO RELATED APPLICATION

This U.S. non-provisional application claims priority under 35 USC § 119 to Korean Patent Application No. 10-2025-0020691, filed on February 18, 2025, in the Korean Intellectual Property Office, the disclosure of which is incorporated by reference herein in its entirety.

### BACKGROUND

Memory devices such as a flash memory device, a resistive memory device, etc., may store data in accordance with a plurality of threshold voltage distributions or a plurality of resistance distributions.

### SUMMARY

As described above, memory devices may store data in accordance with a plurality of threshold voltage distributions or a plurality of resistance distributions. Each respective threshold voltage distribution or resistance distribution may be assigned to a corresponding logic state for stored data. The data stored by a memory cell may be read by determining whether the memory cell is turned on or off when a predetermined read voltage is applied. During and/or following the programming of a memory cell, the intended threshold voltage distribution or resistance distribution of the memory cell may be undesirably distorted due to a number of events or conditions including, e.g., charge leakage, program disturbances, read disturbances, word and/or bitline coupling, temperature change, voltage change, degeneration of the memory cell, etc. For example, the intended threshold voltage distribution or resistance distribution may be shifted and/or broadened and cause a read error such that wrong data different from the stored data are read out.

Implementations of the present disclosure provide a nonvolatile memory device and a method of operating a nonvolatile memory device that are capable of enhancing charge retention characteristics or data retention characteristics of memory cells.

An aspect of the present disclosure provides a nonvolatile memory device that includes a memory cell array including a plurality of memory cell, and peripheral circuits. The peripheral circuits perform an erase operation to release electrons in charge storage regions of the plurality of memory cells of the nonvolatile memory device. After performing the erase operation, the peripheral circuits perform a back-tunneling electron-injection operation to inject electrons into a spacer region between a charge storage region corresponding to a target wordline and a charge storage region corresponding to a neighboring wordline adjacent to the target wordline by applying a back-tunneling voltage to the target wordline and a boosting voltage higher than the back-tunneling voltage to the neighboring wordline. After performing the back-tunneling electron-injection operation, the peripheral circuits perform a program operation to inject electrons into the charge storage region corresponding to the target wordline.

Another aspect of the present disclosure provides a nonvolatile memory device that includes first metal pads disposed in a cell region, second metal pads disposed in a peripheral region under the cell region wherein the peripheral region is vertically connected to the cell region by the first metal pads and the second metal pads, a memory cell array disposed in the cell region, the memory cell array including a plurality of memory cells, and peripheral circuits disposed in the peripheral region. The peripheral circuits are configured to perform an erase operation to release electrons in charge storage regions of the plurality of memory cells of the nonvolatile memory device, after performing the erase operation, perform a back-tunneling electron-injection operation to inject electrons into a spacer region between a charge storage region corresponding to a target wordline and a charge storage region corresponding to a neighboring wordline adjacent to the target wordline by applying a back-tunneling voltage to the target wordline and a boosting voltage higher than the back-tunneling voltage to the neighboring wordline, and after performing the back-tunneling electron-injection operation, perform a program operation to inject electrons into the charge storage region corresponding to the target wordline.

Implementations of the present disclosure may reduce spreading of electrons injected into the charge storage region by injecting electrons into the spacer region to form the potential barrier through the back-tunneling electron-injection operation, thereby improving the data retention characteristics and the reliability of the nonvolatile memory device. The back-tunneling electron-injection operation may reduce performance degradation of the nonvolatile memory device because the back-tunneling electron-injection operation may be performed in a relatively short time, and may reduce degeneration of the memory cells because the back-tunneling electron-injection operation may use the boosting voltage lower than the program voltage and the erase voltage.

### BRIEF DESCRIPTION OF THE DRAWINGS

FIG. 1 is a flowchart illustrating an example method of operating a nonvolatile memory device.

FIG. 2 is a diagram illustrating an example of a cell string included in a nonvolatile memory device.

FIGS. 3 and 4 are diagrams illustrating an example of a back-tunneling electron-injection operation of a nonvolatile memory device.

FIG. 5 is a timing diagram illustrating an example of wordline voltages for a back-tunneling electron-injection operation of a nonvolatile memory device.

FIGS. 6 and 7 are diagrams illustrating examples of a back-tunneling electron-injection operation of nonvolatile memory devices.

FIGS. 8 and 9 are diagrams illustrating examples of a back-tunneling electron-injection operation of nonvolatile memory devices.

FIG. 10 is a block diagram illustrating an example of a storage device

FIG. 11 is a block diagram illustrating an example of a memory controller included in a storage device.

FIG. 12 is a block diagram illustrating an example of a nonvolatile memory device.

FIG. 13 is a block diagram illustrating an example of a memory cell array included in the nonvolatile memory device of FIG. 12.

FIG. 14 is a circuit diagram illustrating an example of circuit of a memory block included in the memory cell array of FIG. 13.

FIG. 15 is a plan view illustrating an example of a nonvolatile memory device.

FIGS. 16 and 17 are cross-sectional views taken along lines I-I’ and II-II’ in FIG. 15, respectively.

FIG. 18 is a diagram illustrating a portion of an example of a cell channel structure corresponding to one memory cell.

FIG. 19 is a circuit diagram illustrating an example of a erase bias condition of a nonvolatile memory device.

FIG. 20 is a circuit diagram illustrating an example of a program bias condition of a nonvolatile memory device.

FIG. 21 is a diagram illustrating an example structure of a cell string of a nonvolatile memory device.

FIG. 22 is a diagram illustrating an example of a horizontal cross-sectional size according a height in a cell string.

FIGS. 23, 24 and 25 are diagrams illustrating examples of voltage regulation for a back-tunneling electron-injection operation in a nonvolatile memory device.

FIG. 26 is a cross-sectional view illustrating an example of a sub-stack division of a nonvolatile memory device.

FIG. 27 is a diagram illustrating an example of voltage regulation for a back-tunneling electron-injection operation of a nonvolatile memory device.

FIG. 28 is a diagram illustrating example states of multi-level cells included in a nonvolatile memory device.

FIGS. 29 and 30 are diagrams illustrating effects of an example method of operating a nonvolatile memory device.

FIG. 31 is a block diagram illustrating an example of a data center including a storage device.

FIG. 32 is a cross-section diagram illustrating an example of a nonvolatile memory device.

FIG. 33 is a diagram illustrating examples manufacturing processes of a stacked semiconductor device.

### DETAILED DESCRIPTION

Various implementations will be described more fully hereinafter with reference to the accompanying drawings, in which some implementations are shown. In the drawings, like numerals refer to like elements throughout. The repeated descriptions may be omitted.

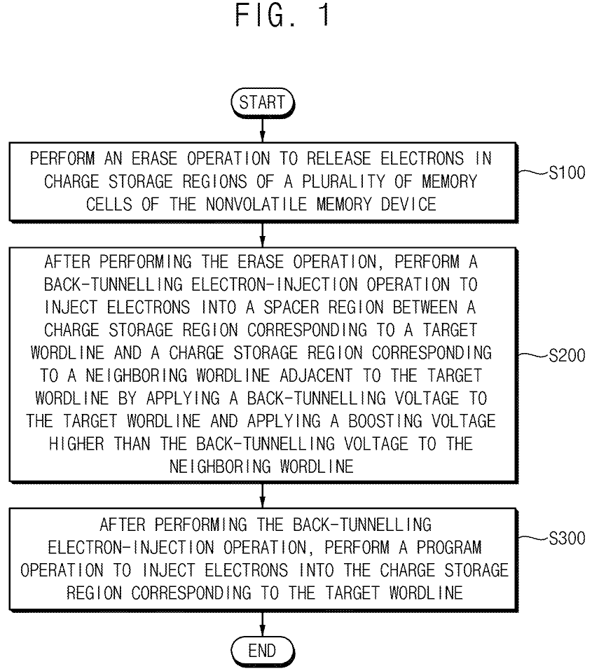

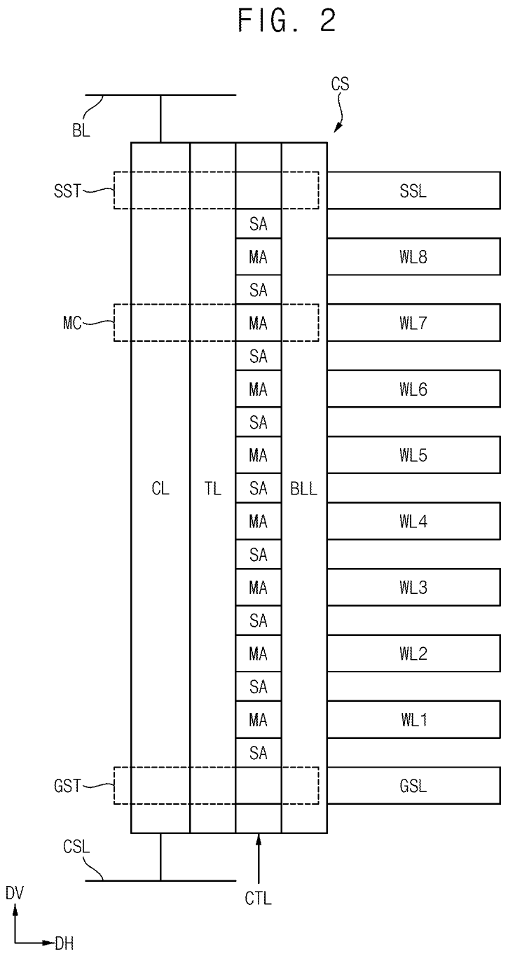

FIG. 1 is a flowchart illustrating a method of operating a nonvolatile memory device according to some implementations, and FIG. 2 is a diagram illustrating a cell string included in a nonvolatile memory device according to some implementations.

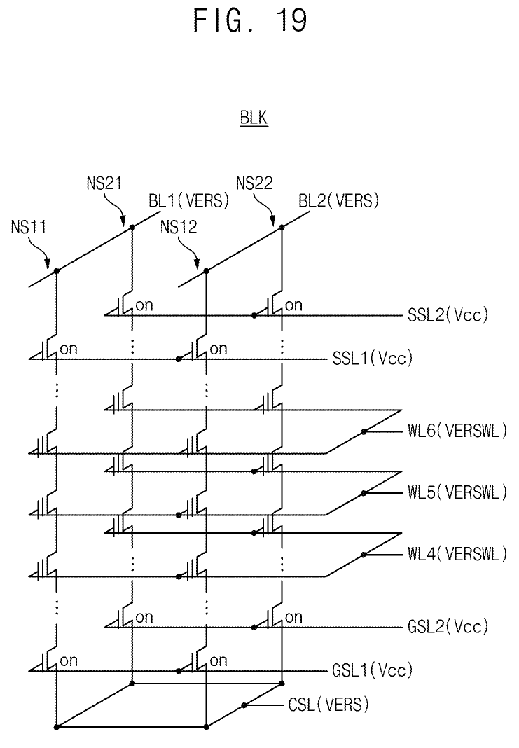

Referring to FIGS. 1 and 2, an erase operation is performed to release electrons in charge storage regions MA of a plurality of memory cells MC of the nonvolatile memory device (S100). The erase operation will be described in more detail with reference to FIG. 19.

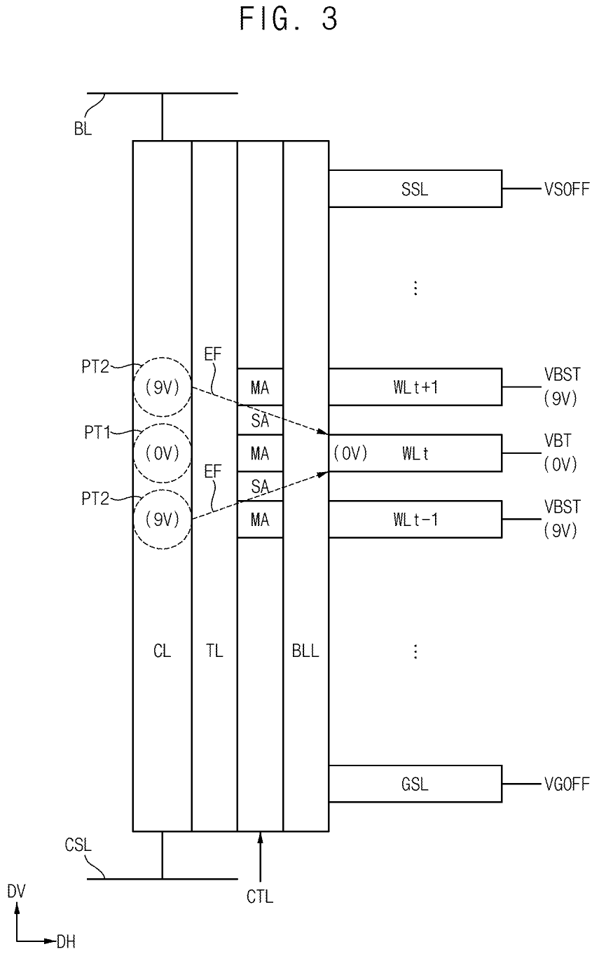

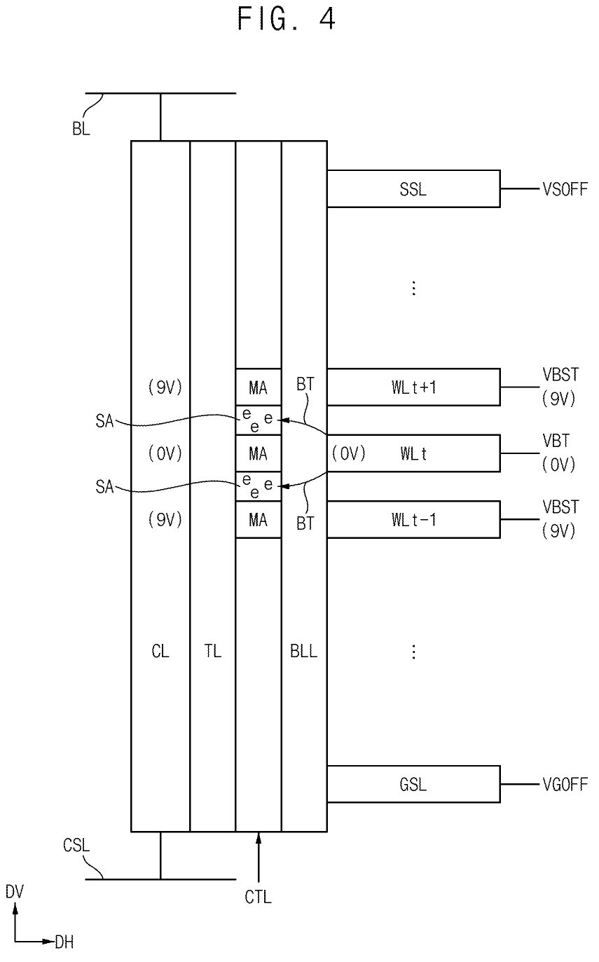

After performing the erase operation, a back-tunneling electron-injection operation is performed to inject electrons into a spacer region between the charge storage region MA corresponding to a target wordline and the charge storage regions MA corresponding to a neighboring wordline adjacent to the target wordline by applying a back-tunneling voltage to the target wordline and applying a boosting voltage higher than the back-tunneling voltage to the neighboring wordline (S200). The back-tunneling electron-injection operation will be described in more detail with reference to FIGS. 3 and 4.

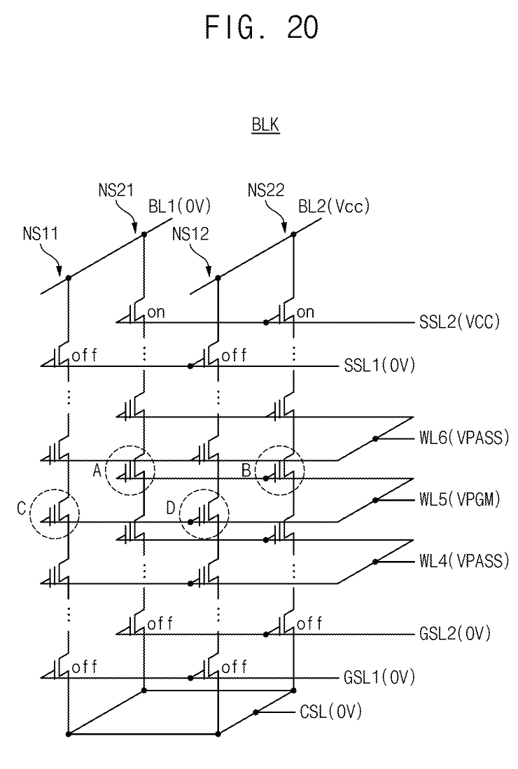

After performing the back-tunneling electron-injection operation, a program operation is performed to inject electrons into the charge storage region MA corresponding to the target wordline (S300). The program operation will be described in more detail with reference to FIG. 20.

As such, the erase operation, the back-tunneling electron-injection operation, and the program operation may be performed sequentially. In general, the erase operation may be performed on a memory block basis, and in some implementations, the back-tunneling electron-injection operation may be performed with respect to the entire memory block after the erase operation is completed. In general, the program operation may be performed on a wordline basis, and in some implementations, the back-tunneling electron-injection operation may be performed with respect to a selected wordline before the program operation is performed. In some implementations, the back-tunneling electron-injection operation may be performed with respect to the entire memory block after the erase operation is completed, and the back-tunneling electron-injection operation may be performed again with respect to the selected wordline before the program operation is performed.

Referring to FIG. 2, a cell string CS may include a string selection transistor SST, a plurality of memory cells MC and a ground selection transistor GST, which are stacked in a vertical direction DV. In a horizontal direction DH of the cell string CS, a string selection line SSL controlling the string selection transistor SST, a plurality of wordlines WL1 to WL8 controlling the plurality of memory cells MC, and a ground selection line GSL controlling the ground selection transistor GST may be disposed. The number of string selection transistors SST, the number of pluralities of memory cells MC, and the number of ground selection transistors GST stacked in each cell string CS may be determined variously. While only one cell string CS is shown in FIG. 2, a plurality of wordlines WL1 to WL8 may be connected in common to a plurality of cell strings, as will be described below.

The cell string CS may include a channel CL, a tunneling insulation layer TL, a charge storage layer CTL, and a blocking insulation layer BLL arranged in the horizontal direction DH. The channel CL, the tunneling insulation layer TL, the charge storage layer CTL, and the blocking insulation layer BLL may extend in the vertical direction DV and shared by the plurality of memory cells MC.

The channel CL may include polysilicon or single crystal silicon and may include impurity regions including p-type impurities such as boron. The channel CL may be connected between the bitline BL and the source line CSL.

The tunneling insulation layer TL may include suitable dielectric material capable of transferring electrons or holes by an injection and extraction mechanism between the channel CL and the charge storage layer CTL. The tunneling insulation layer TL may include, for example, silicon oxide (SiO₂). In some implementations, other dielectric layers or stack structures may be applied to prevent and ameliorate degradation, such as an increase in trapped charge density or breakdown of the tunneling insulation layer TL due to repeated cycles of erase and program operations. Furthermore, suitable dielectric layers may be selected for a tuned band engineered tunnel stack to improve the speed of the erase operation while maintaining good data retention characteristics. The tuned band engineered tunnel stack may be designed to enable hole injection into the charge storage layer CTL during the erase operation to improve the erase speed and prevent cycling degradation. The tunneling insulation layer TL may extend to the transistors GST and SST at the end of the cell string CS to function as a gate insulation layer for the transistors GST and SST.

The charge storage layer CTL may include a dielectric layer with a high free-trap density. The charge storage layer CTL may include silicon nitride or other charge-trapping dielectric. The charge storage layer CTL may extend to adjacent memory cells and may be shared by the plurality of memory cells MC. The charge storage layer CTL may be formed as a whole by units of string, page, block, or plane, without individualization of each memory cell.

The integrally formed charge storage layer CTL includes charge storage regions MA and spacer regions SA. The charge storage regions MA may be allocated respectively to the memory cells and disposed at the same heights of the plurality of wordlines WL1 to WL8. The spacer regions SA may be disposed between the memory cells or between the charge storage regions MA. As shown in FIG. 2, the charge storage regions MA and spacer regions SA may be arranged alternately with each other.

The charge storage regions MA are regions where data or information is programmed or erased, respectively, by the injection or release of charge by the quantum effect of charge, e.g., Fowler-Nordheim tunneling, depending on the direction of the electric field applied between the selected wordline and the channel CL. The charge storage regions MA record information through changes in the threshold voltage of each memory cell depending on the charge stored in each memory cell.

The spacer regions SA are regions to prevent the charge stored in the charge storage regions MA from spreading along the charge storage layer CTL in the direction of the adjacent memory cell in the vertical direction DV, thereby reducing the threshold voltage of the programmed memory cell and preventing read errors. To this end, the spacer regions SA may be charged with a charge of the same polarity as the charge stored for information storage in the charge storage regions MA to form a potential barrier to the programmed charge stored in the charge storage regions MA.

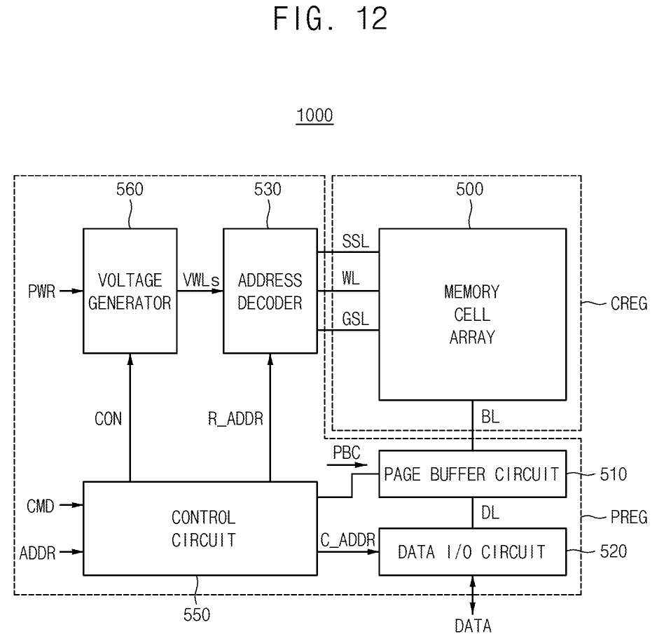

To charge the spacer regions SA with a charge of the same polarity as the charge stored in the charge storage regions MA, the peripheral circuits described below with reference to FIG. 12 may perform the back-tunneling electron-injection operation to inject the charge into the spacer regions SA. The back-tunneling electron-injection operation will be described in more detail with reference to FIGS. 3 and 4.

The blocking insulation layer BLL may prevent the charge trapped in the charge storage layer CTL from diffusing into the wordlines WL1 to WL8. Further, the blocking insulation layer BLL may form a band gap for the back-tunneling electron-injection operation. The blocking insulation layer BLL may include, for example, silicon oxide (SiO₂). In some implementations, for improved data retention, the blocking insulation layer BLL may also include a high permittivity material such as aluminium oxide (Al₂O₃), yttrium oxide (Y₂O₃), silicon nitride (Si₃N₄), tantalum oxide (Ta₂O₅), lanthanum oxide (La₂O₃), hafnium oxide (HfO-₂), or titanium oxide (TiO₂), which may increase the layer thickness while having a good equivalent oxide thickness (EOT).

FIGS. 3 and 4 are diagrams illustrating a back-tunneling electron-injection operation of a nonvolatile memory device according to implementations.

Referring to FIGS. 3 and 4, a turn-off voltage VSOFF may be applied to a string selection line SSL and a turn-off voltage VGOFF may be applied to a ground selection line GSL. In this way, the channel CL of the plurality of memory cells MC may be electrically disconnected from the bitline BL and the source line CSL, that is, the channel CL may be floated while performing the back-tunneling electron-injection operation.

While the channel CL is floated after performing the erase operation, a back-tunneling voltage VBT may be applied to the target wordline WLt and a boosting voltage VBST higher than the back-tunneling voltage VBT may be applied to one or more neighboring wordlines WLt-1 and WLt+1 adjacent to the target wordline WLt. FIGS. 3 and 4 illustrate an example where the back-tunneling voltage VBT is 0V (volt) and the boosting voltage VBST is 9V, but implementations are not limited to thereto. In some implementations, the boosting voltage VBST may have a positive voltage level and the back-tunneling voltage VBT may have a negative voltage level. The difference between the boosting voltage VBST and the back-tunneling voltage VBT may be 5V through 15V. According to some implementations, the boosting voltage VBST may be equal to the program pass voltage VPASS (see FIG. 20) applied to the unselected wordlines during program operation.

While performing the back-tunneling electron-injection operation, a first portion PT1 of the channel CL corresponding to the target wordline WLt may be boosted to the back-tunneling voltage VBT and a second portion PT2 of the channel CL corresponding to the neighboring wordlines WLt-1 and WLt+1 may be boosted to the boosting voltage VBST.

Thus, an electric field EF may be formed in the diagonal direction from the second portion PT2 of the channel CL to the target wordline WLt while performing the back-tunneling electron-injection operation. By such diagonal electric field EF, electrons may be injected from the target wordline WLt into the spacer region SA between the charge storage region MA corresponding to the target wordline WLt and the charge storage regions MA corresponding to the neighboring wordlines WLt-1 and WLt+1.

The erase operation and the program operation may be performed by front-tunneling, in which electrons penetrate the tunneling insulation layer TL between the charge storage region MA and the channel CL. On the other hand, the back-tunneling electron-injection operation may be performed by back-tunneling BT, in which electrons penetrate the blocking insulation layer BLL between the spacer region SA and the target wordline WLt.

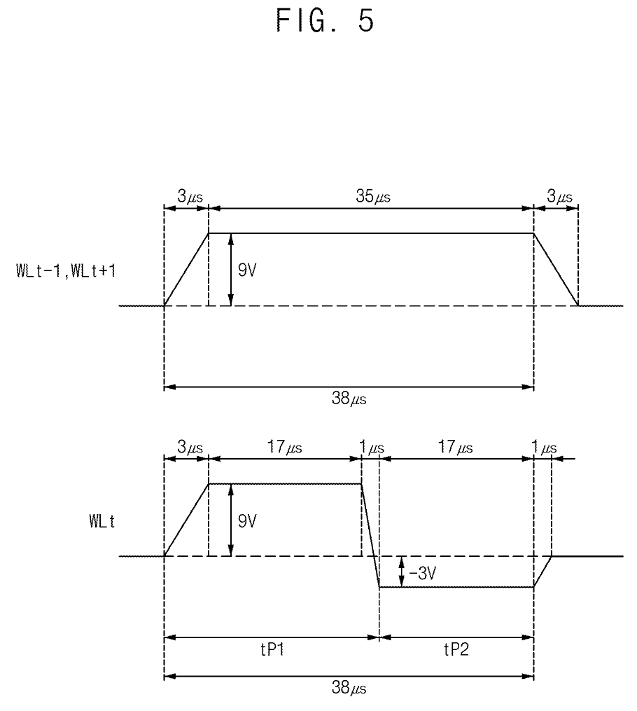

FIG. 5 is a timing diagram illustrating some implementations of wordline voltages for a back-tunneling electron-injection operation of a nonvolatile memory device according to some implementations.

FIG. 5 illustrates voltage levels and timings of voltages applied to the neighboring wordlines WLt-1 and WLt+1 and the target wordline WLt during a back-tunneling electron-injection operation. In FIG. 5, an example with a boosting voltage VBST of 9V and a back-tunneling voltage VBT of -3V is shown, but implementations are not limited thereto.

As shown in FIG. 5, the boosting voltage VBST may have a positive voltage level and the back-tunneling voltage VBT may have a negative voltage level. The boosting voltage VBST and the back-tunneling voltage VBT may be set to any suitable voltage levels to reduce degradation of the memory cells and increase back-tunneling. According to some implementations, the boosting voltage VBST may have a voltage level of 5V to 15V and the back-tunneling voltage VBT may have a voltage level of -5V to 3V.

Referring to FIG. 5, the boosting voltage VBST may be applied to the target wordline WLt and the neighboring wordlines WLt-1 and WLt+1 during a first operation period tP1. The boosting voltage VBST applied to the neighboring wordlines WLt-1 and WLt+1 may be maintained during a second operation period tP2 after the first operation period tP1. On the other hand, the back-tunneling voltage VBT may be applied to the target wordline WLt during the second operation period tP2. In the first operation period tP1, the channel CL may be boosted to the boosting voltage VBST as a whole, and in the second operation period tP2, the first portion of the channel corresponding to the target wordline WLt may be quickly boosted to the back-tunneling voltage VBT. Thus, electron-injection into the spacer region SA by back-tunneling as described above in the second operation period tP2 may be efficiently implemented.

As shown in FIG. 5, the back-tunneling electron-injection operation according to some implementations may reduce performance degradation of nonvolatile memory devices because the back-tunneling electron-injection operation may be performed in a relatively short time of about 40μs. Furthermore, degradation of memory cells may be reduced due to the use of a boosting voltage VBST that is lower than the program voltage and erase voltage, which require 15V or more.

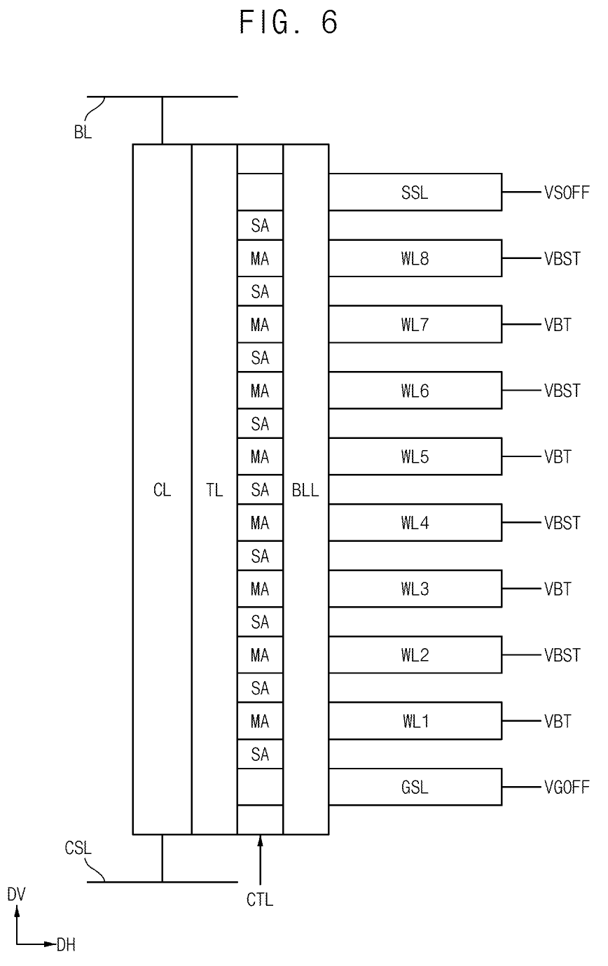

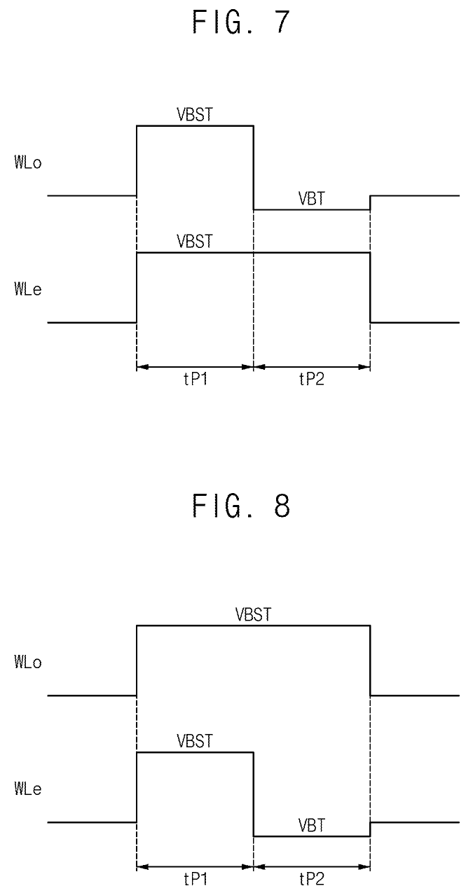

FIGS. 6 and 7 are diagrams illustrating some implementations of a back-tunneling electron-injection operation of nonvolatile memory devices according to some implementations.

Referring to FIGS. 6 and 7, a turn-off voltage VSOFF may be applied to a string selection line SSL and a turn-off voltage VGOFF may be applied to a ground selection line GSL to float a channel CL.

While the channel CL of the plurality of memory cells MC is floated, a boosting voltage VBST may be applied to even-numbered wordlines WL2, WL4, WL6 and WL8 of the plurality of wordlines WL1 to WL8 connected to the plurality of memory cells MC. While applying the boosting voltage VBST to the even-numbered wordlines WL2, WL4, WL6 and WL8, a back-tunneling voltage VBT may be applied to the odd-numbered wordlines WL1, WL3, WL5 and WL7 of the plurality of wordlines WL1 to WL8, for example during the second operation period tP2. As a result, electrons may be injected into all spacer regions SA, and the back-tunneling electron-injection operation may be performed over the entire memory block including the cell string CS.

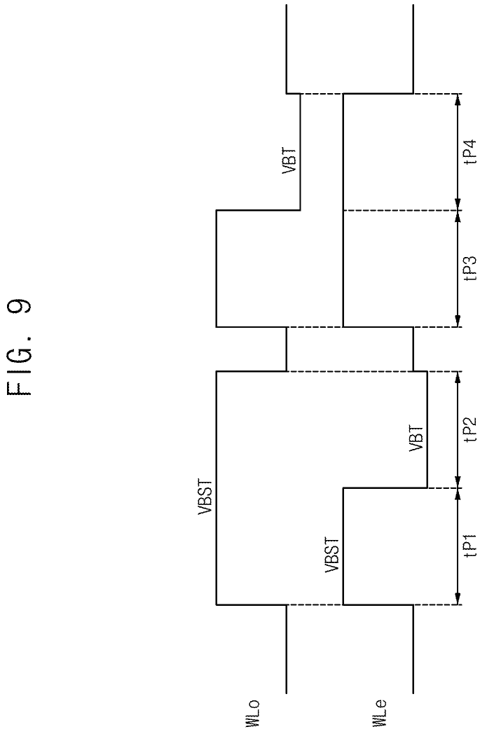

FIGS. 8 and 9 are diagrams illustrating some implementations of a back-tunneling electron-injection operation of a nonvolatile memory device according to some implementations. Hereinafter, description that is redundant with FIGS. 6 and 7 is omitted.

Referring to FIGS. 2 and 8, a boosting voltage VBST may be applied to odd-numbered wordlines WL1, WL3, WL5 and WL7 of the plurality of wordlines WL1 to WL8 connected to the plurality of memory cells MC while the channels CL of the plurality of memory cells MC are floated. While applying the boosting voltage VBST to the odd wordlines WL1, WL3, WL5 and WL7, a back-tunneling voltage VBT may be applied to the even-numbered wordlines WL2, WL4, WL6 and WL8, for example during the second operation period tP2. As a result, all spacer regions SA may be injected with electrons, and the back-tunneling electron-injection operation may be performed with respect to the entire memory block including the cell string CS.

FIG. 9 illustrates some implementations in which the back-tunneling electron-injection operation of FIG. 8 is performed again after performing the back-tunneling electron-injection operation of FIG. 7. According to some implementations, the back-tunneling electron-injection operation of FIG. 7 may be performed first and then the back-tunneling electron-injection operation of FIG. 8 may be performed.

Referring to FIGS. 2 and 9, a boosting voltage VBST may be applied to odd-numbered wordline WL1, WL3, WL5 and WL7 of the plurality of wordlines WL1 to WL8 connected to the plurality of memory cells MC while the channel CL of the plurality of memory cells MC is floated. While applying the boosting voltage VBST to the odd-numbered wordlines WL1, WL3, WL5 and WL7, a back-tunneling voltage VBT may be applied to the even-numbered wordlines WL2, WL4, WL6 and WL8, for example during the second operation period tP2. After that, while the channel CL of the plurality of memory cells MC is floated, the boosting voltage VBST may be applied to the even-numbered wordlines WL2, WL4, WL6 and WL8. While applying the boosting voltage VBST to the even-numbered wordlines WL2, WL4, WL6 and WL8, the back-tunneling voltage VBT may be applied to the odd-numbered wordlines WL1, WL3, WL5 and WL7 of the plurality of wordlines WL1 to WL8, for example during the fourth operation period tP4. As a result, electrons may be injected into all spacer regions SA, and the back-tunneling electron-injection operation may be performed with respect to the entire memory block including the cell string CS. Furthermore, by performing the back-tunneling electron-injection operation in duplicate, the distribution of electrons injected into the spacer regions SA may become more uniform.

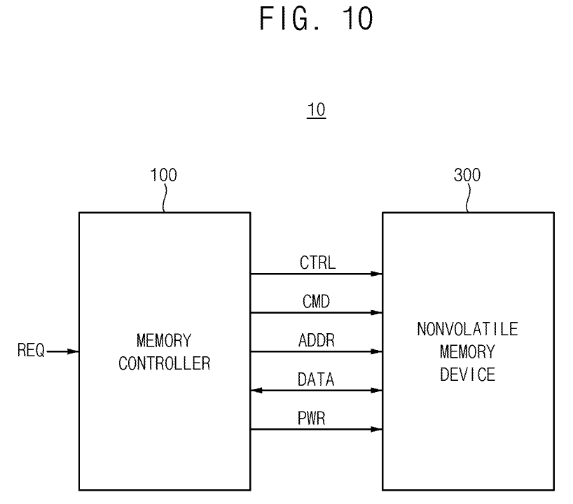

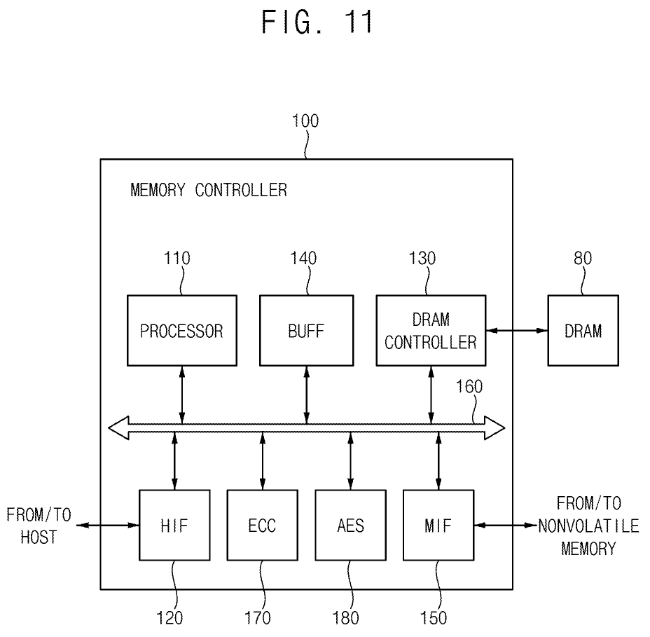

FIG. 10 is a block diagram illustrating a storage device according to some implementations.

Referring to FIG. 1, a memory system or storage device 10 may include a memory controller (or storage controller) 100 and at least one nonvolatile memory device 300. The storage device 10 illustrated in FIG. 10 may include a data storage medium based on flash memory, such as a memory card, USB memory, SSD, or the like.

The nonvolatile memory device 300 may perform erase, write, or read operations, or the like, under control of the memory controller 100. The nonvolatile memory device 300 receives commands CMD such as read commands and write commands, and addresses ADDR such as read addresses and write addresses, from the memory controller 100 via input and output lines, and transfers and receives data DATA for the read operations or the write operations (or program operations) with the memory controller 100. The nonvolatile memory device 300 may receive a control signal CTRL via a control line, and the nonvolatile memory device 300 may receive power PWR from the memory controller 100.

The memory controller 100 may control access to the nonvolatile memory device 300 based on requests REQ received from an external host device.

FIG. 11 is a block diagram illustrating some implementations of a memory controller included in a storage device according to some implementations.

Referring to FIG. 11, a memory controller or storage controller 100 may include a processor 110, a buffer memory (BUFF) 140, a DRAM controller 130, a host interface (HIF) 120, an error correction code (ECC) engine 170, a memory interface (MIF) 150, an advanced encryption standard (AES) engine 180, and an internal bus 160 electrically connecting the components.

The processor 110 may control the operation of the storage controller 100 in response to commands received via the host interface 120 from an external host device. For example, the processor 110 may control the operation of a storage device (e.g., 10 in FIG. 10) and may employ firmware to drive the memory system 10 to control respective components.

The buffer memory 140 may store instructions and data that are executed and processed by the processor 110. For example, the buffer memory 140 may be implemented as volatile memory, such as SRAM, DRAM, or the like.

The ECC engine 170 for error correction may perform ECC encoding and ECC decoding using error correction code such as Bose-Chaudhuri-Hocquenghem (BCH) code, Low Density Parity Check (LDPC) code, Turbo Code, Reed-Solomon Code, Convolution Code, Recursive Systematic Code (RSC), Coded Modulation, such as Trellis-Coded Modulation (TCM), Block Coded Modulation (BCM), Hamming code, and so on.

The host interface 120 may provide a physical connection between the host device and the storage controller 100, i.e., the host interface 120 may provide interfacing with the storage controller 100 in a bus format corresponding to the bus format of the host device. In some implementations, the bus format of the host device may be SCSI or SAS. In some implementations, the bus format of the host device may be USB, peripheral component interconnect express (PCIe), ATA, PATA, SATA, NVMe, or the like.

The memory interface 150 may exchange data with a nonvolatile memory device (e.g., 300 in FIG. 10). The memory interface 150 may transfer write data to the nonvolatile memory device 300 and may receive read data from the nonvolatile memory device 300. For example, the memory interface 150 may utilize a standard protocol such as Toggle or ONFI.

The AES engine 180 may perform at least one of encryption operations and decryption operations on data input to the storage controller 100, using a symmetric-key algorithm. Although not shown in detail, the AES engine 180 may include an encryption module and a decryption module. Depending on examples, the encryption module and the decryption module may be implemented as separate modules or may be implemented as a single module.

The processor 110 may access an external DRAM 80 via the DRAM controller 130. The processor 110 may control the DRAM controller 130, the memory interface 150, and the host interface 120 to transfer user data stored in the external DRAM 80 to the nonvolatile memory device 300 or to an external host device.

FIG. 12 is a block diagram illustrating a nonvolatile memory device according to some implementations.

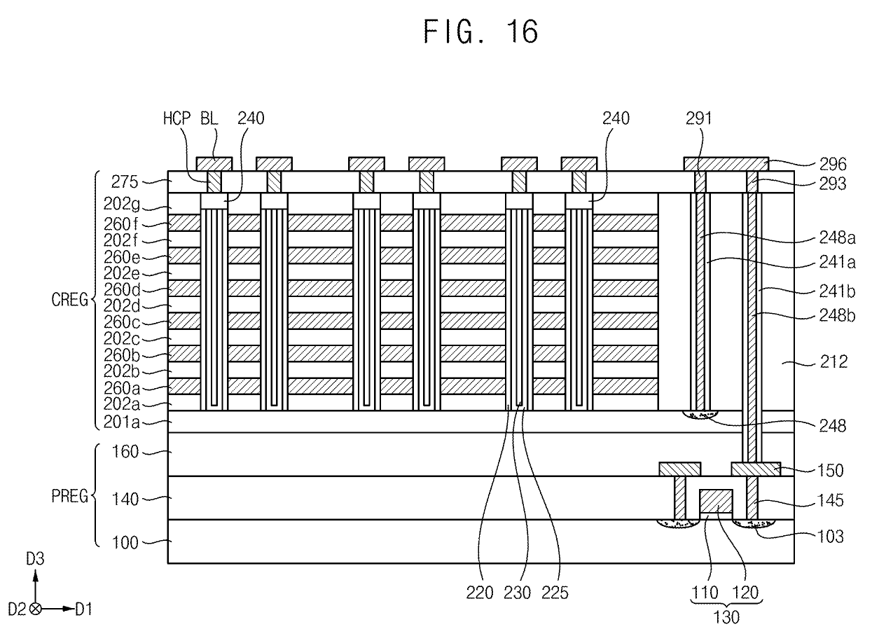

Referring to FIG. 12, a nonvolatile memory device 1000 may include a memory cell array 500, a page buffer circuit 510, a data input/output (I/O) circuit 520, an address decoder 530, a control circuit 550 and a voltage generator 560. The memory cell array 500 may be disposed in a cell region CREG in FIG. 16, and peripheral circuits such as the page buffer circuit 510, the data I/O circuit 520, the address decoder 530, the control circuit 550 and the voltage generator 560 may be disposed in a peripheral region PREG in FIG. 16.

The memory cell array 500 may be coupled to the address decoder 530 through string selection lines SSL, wordlines WL, and ground selection lines GSL. In addition, the memory cell array 500 may be coupled to the page buffer circuit 510 through a bitlines BL. The memory cell array 500 may include a memory cells coupled to the wordlines WL and the bitlines BL. In some implementations, the memory cell array 500 may be a three-dimensional memory cell array, which is formed on a substrate in a three-dimensional structure (for example, a vertical structure). In this case, the memory cell array 500 may include cell strings (e.g., NAND strings) that are vertically oriented such that at least one memory cell is overlapped vertically with another memory cell.

The control circuit 550 may receive a command (signal) CMD and an address (signal) ADDR from a memory controller. Accordingly, the control circuit 550 may control erase, program (or write) and read operations of the nonvolatile memory device 1000 in response to (or based on) at least one of the command signal CMD and the address signal ADDR. An erase operation may include performing a sequence of erase loops, and a program operation may include performing a sequence of program loops. Each program loop may include a program operation and a program verification operation. Each erase loop may include an erase operation and an erase verification operation. The read operation may include a normal read operation and data recover read operation.

For example, the control circuit 550 may generate the control signals CTL used to control the operation of the voltage generator 560, and may generate the page buffer control signal PBC for controlling the page buffer circuit 510 based on the command signal CMD, and generate the row address R_ADDR and the column address C_ADDR based on the address signal ADDR. The control circuit 550 may provide the row address R_ADDR to the address decoder 530 and provide the column address C_ADDR to the data I/O circuit 520.

The address decoder 530 may be coupled to the memory cell array 500 through the string selection lines SSL, the wordlines WL, and the ground selection lines GSL. During the program operation or the read operation, the address decoder 530 may determine or select one of the wordlines WL as a selected wordline and determine the remaining wordlines WL except for the selected wordline as unselected wordlines based on the row address R_ADDR.

During the program operation or the read operation, the address decoder 530 may determine one of the string selection lines SSL as a selected string selection line and determine rest of the string selection lines SSL except for the selected string selection line as unselected string selection lines based on the row address R_ADDR.

The voltage generator 560 may generate wordline voltages VWL, which are required for the operation of the memory cell array 500 of the nonvolatile memory device 1000, based on the control signals CTL. The voltage generator 560 may receive power PWR from the memory controller. The wordline voltages VWL may be applied to the wordlines WL through the address decoder 530.

For example, during the erase operation, the voltage generator 560 may apply an erase voltage to a well and/or a common source line of a memory block and apply an erase permission voltage (e.g., a ground voltage) to all or a portion of the wordlines of the memory block based on an erase address. During the erase verification operation, the voltage generator 560 may apply an erase verification voltage simultaneously to all of the wordlines of the memory block or sequentially (e.g., one by one) to the wordlines.

For example, during the program operation, the voltage generator 560 may apply a program voltage to the selected wordline and may apply a program pass voltage to the unselected wordlines. In addition, during the program verification operation, the voltage generator 560 may apply a program verification voltage to the first wordline and may apply a verification pass voltage to the unselected wordlines.

During the normal read operation, the voltage generator 560 may apply a read voltage to the selected wordline and may apply a read pass voltage to the unselected wordlines. During the data recover read operation, the voltage generator 560 may apply the read voltage to a wordline adjacent to the selected wordline and may apply a recover read voltage to the selected wordline.

The page buffer circuit 510 may be coupled to the memory cell array 500 through the bitlines BL. The page buffer circuit 510 may include multiple buffers. In some implementations, each buffer may be connected to a single bitline. In some implementations, each buffer may be connected to two or more bitlines. The page buffer circuit 510 may temporarily store data to be programmed in a selected page or data read out from the selected page of the memory cell array 500.

The data I/O circuit 520 may be coupled to the page buffer circuit 510 through data lines DL. During the program operation, the data I/O circuit 520 may receive program data DATA received from the memory controller and provide the program data DATA to the page buffer circuit 510 based on the column address C_ADDR received from the control circuit 550. During the read operation, the data I/O circuit 520 may provide read data DATA, having been read from the memory cell array 500 and stored in the page buffer circuit 510, to the memory controller based on the column address C_ADDR received from the control circuit 550.

In addition, the page buffer circuit 510 and the data I/O circuit 520 may read data from a first area of the memory cell array 500 and write the read data to a second area of the memory cell array 500 (e.g., without transmitting the data to a source external to the nonvolatile memory device 1000, such as to the memory controller). For example, the page buffer circuit 510 and the data I/O circuit 520 may perform a copy-back operation. The page buffer circuit 510 and the data I/O circuit 520 may be controlled by the control circuit 550.

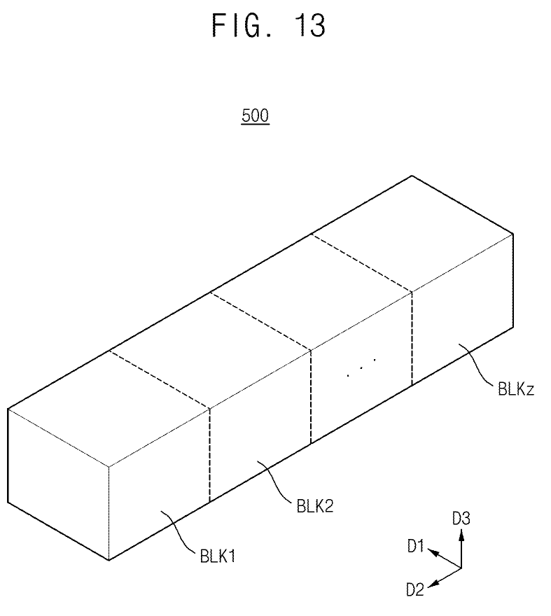

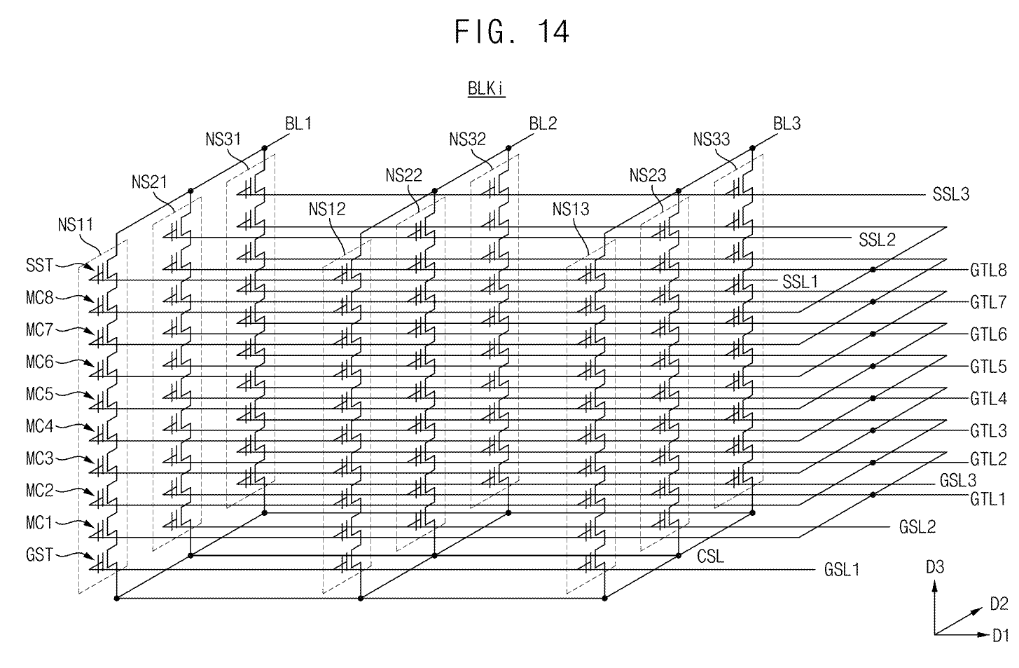

FIG. 13 is a block diagram illustrating a memory cell array included in the nonvolatile memory device of FIG. 12, and FIG. 14 is a circuit diagram illustrating an equivalent circuit of a memory block included in the memory cell array of FIG. 13.

Hereinafter, a vertical direction D3 indicates a direction perpendicular to an upper surface of a semiconductor substrate, and a first horizontal direction D1 and a second horizontal direction D2 indicate two directions parallel to the upper surface of the semiconductor substrate. The first horizontal direction D1 and the second horizontal direction D2 may be substantially perpendicular. The first horizontal direction D1 may be referred to as a row direction or a first direction, the second horizontal direction D2 may be referred to as a column direction or a second direction and the vertical direction D3 may be referred to as a third direction. The direction indicated by an arrow in figures and the opposite direction may be considered as the same direction.

Referring to FIG. 13, the memory cell array 500 may include memory blocks BLK1 to BLKz. In some implementations, the memory blocks BLK1 to BLKz may be selected by the address decoder 530 of FIG. 12. For example, the address decoder 530 may select a particular memory block BLK corresponding to a block address among the memory blocks BLK1 to BLKz.

The memory block BLKi of FIG. 14 may be formed on a substrate in a three-dimensional structure (for example, a vertical structure). For example, NAND strings or cell strings included in the memory block BLKi may be disposed in the vertical direction D3 perpendicular to the upper surface of the substrate.

Referring to FIG. 14, the memory block BLKi may include NAND strings NS11 to NS33 coupled between bitlines BL1, BL2 and BL3 and a common source line CSL. Each of the NAND strings NS11 to NS33 may include a string selection transistor SST, a memory cells MC1 to MC8, and a ground selection transistor GST. In FIG. 14, each of the NAND strings NS11 to NS33 is illustrated to include eight memory cells MC1 to MC8. However, implementations are not limited thereto. In some implementations, each of the NAND strings NS11 to NS33 may include any number of memory cells.

Each string selection transistor SST may be connected to a corresponding string selection line (for example, one of SSL1 to SSL3). The memory cells MC1 to MC8 may be connected to corresponding gate lines GTL1 to GTL8, respectively. The gate lines GTL1 to GTL8 may be wordlines, and some of the gate lines GTL1 to GTL8 may be dummy wordlines. Each ground selection transistor GST may be connected to a corresponding ground selection line (for example, one of GSL1 to GSL3). Each string selection transistor SST may be connected to a corresponding bitline (e.g., one of BL1, BL2 and BL3), and each ground selection transistor GST may be connected to the common source line CSL.

Wordlines WL having the same height may be commonly connected, and the ground selection lines GSL1 to GSL3 and the string selection lines SSL1 to SSL3 may be separated. In FIG. 14, the memory block BLKi is illustrated to be coupled to eight gate lines GTL1 to GTL8 and three bitlines BL1 to BL3. However, implementations are not limited thereto. Each memory block in the memory cell array 500 may be coupled to any number of wordlines and any number of bitlines.

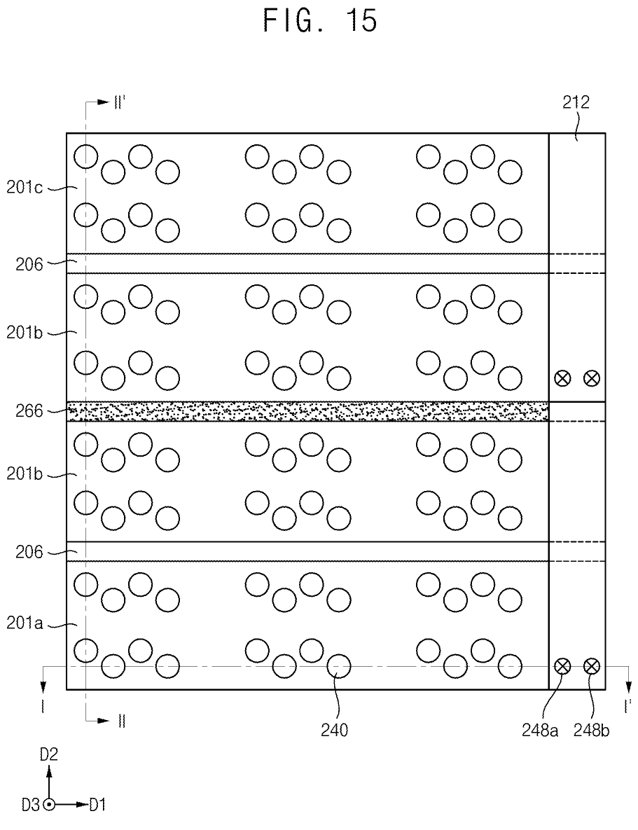

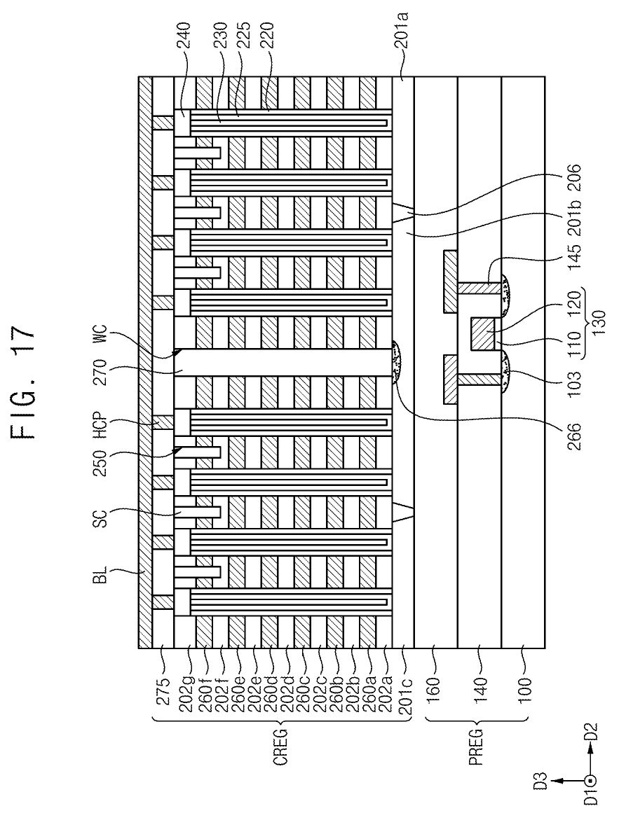

FIG. 15 is a plan view illustrating a nonvolatile memory device according to some implementations, and FIGS. 16 and 17 are cross-sectional views taken along lines I-I’ and II-II’ in FIG. 15, respectively.

The nonvolatile memory device illustrated in FIGS. 15 through 17 may have a cell over periphery (COP) structure in which a memory cell structure is stacked on peripheral circuits. The memory cell structure may have a vertical NAND flash memory device structure in which a plurality of NAND flash memory cells are formed vertically, that is, in the vertical direction D3 perpendicular to a top surface of a substrate.

For clear and concise description, some elements of the memory device may not be shown in FIG. 15. For example, FIG. 15 illustrates base layer patterns 201a, 201b and 201c, separation layer patterns 206, a second impurity region 266, pads 240, a mold protection layer 212, a first connecting contact 248a and a second connecting contact 248b, and the other elements than described above are omitted.

Referring to FIGS. 15 through 17, the memory device may include a peripheral region PREG including a peripheral circuit structure and a cell region CREG including a memory cell structure.

The peripheral circuit structure may include, e.g., a transistor including a gate structure 130 and a source/drain region 103 formed on a substrate 100, lower insulation layers 140 and 160, a lower contact 145, and lower wirings 150.

The substrate 100 may include a semiconductor material, e.g., single crystalline silicon or a single crystalline germanium. The gate structure 130 may include a gate insulation layer pattern 110 and a gate electrode 120, which are stacked on the substrate 100. The transistor, which includes the gate structure 130 and the source/drain region 103, may be disposed and defined on the substrate 100.

The gate insulation layer pattern 110 may include, e.g., silicon oxide or a metal oxide. The gate electrode 120 may include, e.g., a metal, a metal nitride or doped polysilicon. The source/drain region 103 may include n-type or p-type impurities.

A first lower insulation layer 140 may be formed on the substrate 100 and cover the transistor, and the lower contact 145 may extend through the first lower insulation layer 140 to be electrically connected to the source/drain region 103.

The lower wirings 150 may be disposed on the first lower insulation layer 140 and may be electrically connected to the lower contact 145 and the through-substrate via 145 respectively. A second lower insulation layer 160 may be formed on the first lower insulation layer 140 and cover the lower wirings 150. FIG. 16 illustrates a non-limiting example that the lower wirings 150 are disposed in the same layer, but the lower wirings may be distributed in different wiring layers.

The first and second lower insulation layers 140 and 160 may include an insulating material, e.g., silicon oxide. The lower contact 145 and the lower wirings 150 may include a conductive material, e.g., a metal, a metal nitride or doped polysilicon.

The memory cell structure may include first to third base layer patterns 201a, 201b and 201c, a channel 225, the gate line 260, a bitline BL and a connecting wiring 296.

The separation layer pattern 206 may extend in the row direction D1, and a plurality of the separation layer patterns 206 may be arranged in the column direction D2. Thus, a base layer may be physically divided into the first to third base layer patterns 201a, 201b and 201c. FIGS. 15 through 17 illustrate three base layer patterns 201a, 201b and 201c, however, the number of the base layer patterns is not necessarily limited herein.

The base layer patterns 201a, 201b and 201c may include polysilicon or single crystalline silicon. In some implementations, the base layer patterns 201a, 201b and 201c may further include p-type impurities such as boron (B). In this case, the base layer patterns 201a, 201b and 201c may serve as a p-type well.

The separation layer pattern 206 may extend linearly in the row direction D1. The base layer patterns 201a, 201b and 201c may be physically separated by the separation layer pattern 206. The separation layer pattern 206 may include an insulation layer pattern, e.g., a silicon oxide pattern.

The channel 225 may be disposed on the base layer patterns 201a, 201b and 201c, and may extend in vertical direction D3 from top surfaces of the base layer patterns 201a, 201b and 201c. The channel 225 may have a hollow cylindrical shape or a cup shape. The channel 225 may include polysilicon or single crystalline silicon, and may include an impurity region doped with, e.g., p-type impurities such as boron.

A plurality of the channels 225 may be arranged in the row direction D1 to form a channel row, and a plurality of the channel rows may be arranged in the column direction D2. In some implementations, the channels 225 included in the neighboring channel rows may be arranged in a zigzag arrangement. Thus, a number of the channels 225 in a unit area of the base layer pattern 201a, 201b and 201c may be increased, and accordingly, a channel density may increase.

A filling layer pattern 230 may be disposed in an inner space of the channel 225. The filling layer pattern 230 may have a pillar shape or a solid cylindrical shape. The filling layer pattern 230 may include an insulation layer pattern, e.g., silicon oxide.

According to some implementations, the filling layer pattern 230 may be omitted, and the channel 225 may have a pillar shape or a solid cylindrical shape. A dielectric layer structure 220 may be formed on an outer sidewall of the channel 225. The dielectric layer structure 220 may have a cup shape wherein a bottom portion is exposed, or a hollow cylindrical shape.

The dielectric layer structure 220 may include a tunneling insulation layer, a charge storage layer and a blocking layer which may be sequentially stacked from the outer sidewall of the channel 225. The blocking layer may include silicon oxide or a metal oxide such as hafnium oxide or aluminum oxide. The charge storage layer may include a nitride such as silicon nitride or a metal oxide, and the tunneling insulation layer may include an oxide such as silicon oxide. For example, the dielectric layer structure 220 may have an oxide-nitride-oxide (ONO) stack layer structure.

The pad 240 may be formed on the filling layer pattern 230, the channel 225 and the dielectric layer structure 220. For example, the filling layer pattern 230, the channel 225 and the dielectric layer structure 220 may be capped or at least partially covered by the pad 240. The pad 240 may include a polysilicon or single crystalline silicon. The pad 240 may further include n-type impurities, for example, phosphorus (P) or arsenic (As).

As illustrated in FIG. 15, a plurality of the pads 240 may be arranged in the row direction D1 to form a pad row pattern substantially similar to the channel row pattern. A plurality of the pad rows may be arranged in the column direction D2.

The gate lines 260 (e.g., 260a through 260f) may be disposed on an outer sidewall of the dielectric layer structure 220 and may be spaced apart from each other vertically in the third direction D3. In some implementations, each gate line 260 may surround the channels 225 of at least one channel row and may extend in the first direction D1.

For example, as illustrated in FIGS. 15 through 17, each gate line 260 may surround six channel rows, however, the number of the channel rows surrounded by each gate line 260 is not necessarily limited.

The gate line 260 may include a metal having a low electrical resistance and/or a nitride thereof. For example, the gate line 260 may include tungsten (W), tungsten nitride, titanium (Ti), titanium nitride, tantalum (Ta), tantalum nitride, platinum (Pt), or the like. In some implementations, the gate line 260 may have a multi-layered structure including a barrier layer formed of a metal nitride and a metal layer.

For example, a lowermost gate line 260a may serve as a ground selection line GSL. Four gate lines 260b, 260c, 260d and 260e on the GSL may serve as wordlines. An uppermost gate line 260f on the wordlines may serve as a string selection line SSL.

In this case, the GSL may be formed at a single level, the wordlines may be formed at four levels, and the SSL may be formed at a single level. However, each of the number of levels of the GSL, the wordline and the SSL is not necessarily limited. According to some implementations, the GSL and the SSL may be formed at two levels, respectively, and the wordline may be formed at 2^n levels such as 4, 8 or 16 levels. The stacked number of the gate lines 260 may be determined variously in consideration of a circuit design and a degree of integration of the semiconductor device.

Insulating interlayers 202 (e.g., 202a to 202g) may be disposed between the gate lines 260 neighboring along the vertical direction D3. The insulating interlayers 202 may include a silicon oxide-based material, e.g., silicon dioxide (SiO₂), silicon oxycarbide (SiOC) or silicon oxyfluoride (SiOF). The gate lines 260 may be insulated from each other along the vertical direction D3 by the insulating interlayers 202.

The wordline cut pattern 270 or the wordline cut region WC may be formed through the gate lines 260 and the insulating interlayers 202 along the vertical direction D3. The wordline cut region WC may have a trench shape or a ditch shape extending in the row direction D1.

The wordline cut pattern 270 extending in the vertical direction D3 may be disposed on the second impurity region 266. A plurality of the second impurity regions 266 and the wordline cut patterns 270 may be arranged along column direction D2. In some implementations, the second impurity region 266 may include n-type impurities, for example, phosphorus (P) or arsenic (As). The wordline cut pattern 270 may include an insulation layer pattern, e.g., silicon oxide. A metal silicide pattern such as a cobalt silicide pattern and/or a nickel silicide pattern may be further formed on the second impurity region 266.

In some implementations, a memory block sharing the gate lines 260 may be defined by the wordline cut pattern 270. The memory block may be divided into sub-memory blocks by the separation layer pattern 206. Thus, a size of an individual block may be reduced, and segmented operational control may be achieved.

In some implementations, one of the second impurity regions 266 and one of the wordline cut patterns 270 may be provided per each base layer pattern 201a, 201b and 201c. As illustrated in FIG. 17, for example, the second impurity region 266 may be formed at a central region of the second base layer pattern 201b, and the wordline cut pattern 270 may be disposed on the second impurity region 266.

A connecting contact or a vertical contact and a connecting wiring may be provided for each base layer pattern 201a, 201b and 201c to transfer an electrical signal and/or a voltage from a peripheral circuit.

In some implementations, the mold protection layer 212 may be formed on lateral portions of the base layer pattern 201a, 201b and 201c, and the separation layer pattern 206. The first connecting contact 248a may extend through the mold protection layer 212 to make contact with a first impurity region 248 formed at the lateral portion of the base layer pattern 201a, 201b and 201c. The second contact 248b may extend through the mold protection layer 212, the base layer pattern 201a, 201b and 201c, and a second lower insulation layer 160 to make contact with a lower wiring 150. A first insulation layer pattern 241a and a second insulation layer pattern 241b may be formed on sidewalls of the first connecting contact 248a and the second connecting contact 248b, respectively.

A first plug 291 and a second plug 293 may extend through an upper insulation layer 275 to be in contact with the first connecting contact 248a and the second connecting contact 248b, respectively. The connecting wiring 296 may be disposed on the upper insulation layer to electrically connect the first and second plugs 291 and 293, respectively.

A string selection line cut pattern 250 may be disposed in the string selection line cut region SC. The string selection line cut pattern 250 may include an insulation material, e.g., silicon oxide.

In some implementations, the string selection line cut region SC or the string selection line cut pattern 250 may provide a separation of the SSL in each memory block. In this case, the string selection line cut region SC or the string selection line cut pattern 250 may extend through an uppermost insulating interlayer 202g and the SSL 260f, and may extend partially through an insulating interlayer 202f directly under the SSL 260f.

An upper insulation layer 275 may be formed on the uppermost insulating interlayer 202g, the pad 240, the string selection line cut pattern 250, the wordline cut pattern 270, the first connecting contact 244a and the second connecting contact 244b.

Channel contact plugs HCP may be formed through the upper insulation layer 275 to make contact with the pad 240. The channel contact plugs HCP may define an arrangement comparable to an arrangement of the channels 225 or the pads 240.

The bitline BL may be disposed on the upper insulation layer 275 to be electrically connected to the channel contact plug HCP. For example, the bitline BL may extend in the second direction D2 to be electrically connected to a plurality of the channel contact plugs HCP. The bitline BL and the separation layer pattern 206 may extend in substantially the same direction.

According to some implementations described above, the base layer may be physically separated by the separation layer pattern 206. Thus, the first to third base layer patterns 201a, 201b and 201c may be capable of being operated independently or individually.

The memory block may be further segmented or divided by the separation layer pattern 206, and thus signal interference or disturbance due to the large size of memory block may be reduced. Thus, reliability of the semiconductor device may be increased.

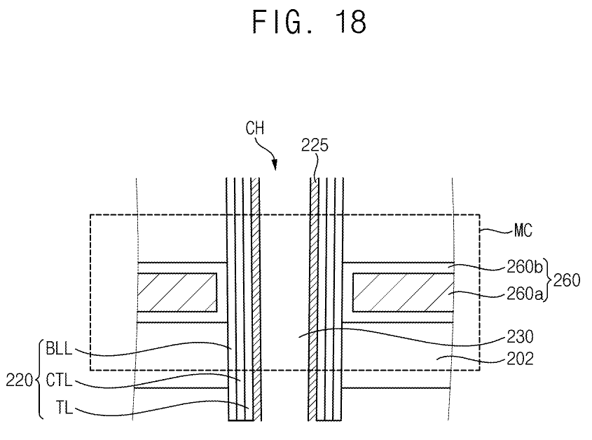

FIG. 18 is a diagram illustrating a portion of a cell channel structure corresponding to one memory cell.

As shown in FIG. 18, the dielectric layer structure 220 may include a tunneling insulation layer TL, a blocking insulation layer BLL, and a charge storage layer CTL. The tunneling insulation layer TL may be disposed adjacent to the channel 225 to enclose or at least partially cover the outer sidewall of the channel 225. The blocking insulation layer BLL may be disposed adjacent to the gate electrodes 260. The charge storage layer CTL may be disposed between the tunneling insulation layer TL and the blocking insulation layer BLL. The tunneling insulation layer TL may include, for example, a silicon oxide layer or a high-k dielectric layer (e.g., aluminum oxide (Al₂O₃) or hafnium oxide (HfO₂)). The blocking insulation layer BLL may include, for example, a silicon oxide layer or a high-k dielectric layer (e.g., aluminum oxide (Al₂O₃) or hafnium oxide (HfO₂)). The charge storage layer CTL may include, for example, a silicon nitride layer. The filling layer pattern 230 may include, for example, a silicon oxide layer, a silicon nitride layer, or a silicon oxynitride layer.

As described above, the pad 240 may be disposed in the upper portion of each cell channel structure CH. The pad 240 may extend laterally to cover the top surface of the channel 225 and a top surface of the dielectric layer structure 220. The pad 240 may at least partially cover or cap at least one of a top surface of the tunneling insulation layer TL, a top surface of the charge storage layer CTL, and a top surface of the blocking insulation layer BLL. For example, as shown in FIG. 16, the pad 240 may cover all of the top surfaces of the tunneling insulation layer TL, the charge storage layer CTL, and the blocking insulation layer BLL. The pad 240 may include a semiconductor material that is doped with impurities of the first conductivity type. As an example, the pad 240 may be a highly doped n-type region.

The channel 225 and the pad 240 may be formed of a semiconductor material (e.g., silicon). As an example, the channel 225 and the pad 240 may include poly silicon. The channel 225 and the pad 240 may have different crystallographic structures from each other.

FIG. 19 is a circuit diagram illustrating an erase bias condition of a nonvolatile memory device according to some implementations.

For convenience of description, NAND strings NS11 and NS21 connected to a first bitline BL1 and NAND strings NS12 and NS22 connected to a second bitline BL2 are illustrated in FIG. 19.

During an erase operation, an erase voltage VERS may be applied to the first bitline BL1 and the second bitline BL2. In this case, the power supply voltage VCC, for example, is applied to the first-string selection line SSL1 and the second-string selection line SSL2. Also, during the erase operation, the erase voltage VERS may be applied to the common source line CSL. In this case, the power supply voltage VCC may be applied to the first ground selection line GSL1 and the second ground selection line GSL2. The erase enable voltage VERSWL may be applied to the wordlines WL4, WL5 and WL6. As a result, the erase operation may be performed by front-tunneling such that electrons penetrate the tunneling insulation layer TL.

Under this erase bias condition, voltages of the drain and source of the memory cells of the memory block may be, for example, 20V, and a voltage of, for example, 0V may be applied to the gate. The voltage generator 560 of FIG. 12 may generate the erase voltage VERS applied to the bitlines BL1 and BL2 and/or the common source line CSL during the erase operation.

FIG. 20 is a circuit diagram illustrating a program bias condition of a nonvolatile memory device according to some implementations.

For convenience of description, NAND strings NS11 and NS21 connected to a first bitline BL1 and NAND strings NS12 and NS22 connected to a second bitline BL2 are illustrated in FIG. 20.

The first bitline BL1 may be a program bitline to which a program permission voltage (e.g., 0V) is applied, and the second bitline BL2 may be a program inhibition bitline to which a program inhibition voltage such as a power supply voltage VCC is applied. If the NAND string NS21 among the NAND strings NS11 and NS21 is selected, during a program operation, a voltage of 0V may be applied to a first-string selection line SSL1, and the power supply voltage VCC may be applied to a second-string selection line SSL2.

The voltage of 0V may be applied to ground selection lines GSL1 and GSL2. Furthermore, a voltage (e.g., VCC) higher than 0V may be applied to a common source line CSL. A program voltage VPGM (e.g., 18V) may be applied to a selected wordline (e.g., WL5) and a pass voltage VPASS (e.g., 8V) may be applied to unselected wordlines (e.g., WL4 and WL6). As a result, the program operation may be performed by front-tunneling such that electrons penetrate the tunneling insulation layer TL.

Under the program bias condition, the program voltage VPGM (e.g., 18V) may be applied to a gate of a memory cell A having a channel voltage of 0V. Because a strong electric field is formed between the gate and a channel of the memory cell A, the memory cell A may be programmed. However, because respective channels of memory cells C and D are in a floating state, channel voltages thereof may be boosted up to, for example, about 8V, and thus, the memory cells C and D may not be programmed. The memory cell B may not be programmed because a weak electric field is formed between the gate of the memory cell B and the channel. The voltage generator 560 in FIG. 12 may generate the program voltage VPGM and the program pass voltage VPASS applied to the plurality of wordlines during the program operation.

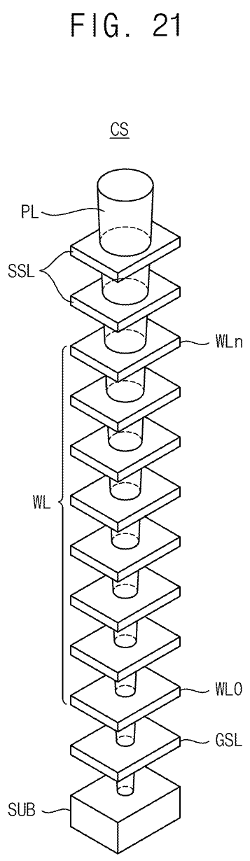

FIG. 21 is a diagram illustrating an example structure of a cell string of a nonvolatile memory device according to some implementations.

Referring to FIG. 21, to form a cell string CS, a pillar PL may be provided such that the pillar PL extends in the vertical direction D3 perpendicular to an upper surface of a semiconductor substrate SUB. The ground selection line GSL, the wordlines WL, and the string selection lines SSL may each be formed of conductive materials, for example, metal materials, that are parallel to the semiconductor substrate SUB. The pillar PL may penetrate the conductive materials forming the ground selection line GSL, the wordlines WL, and the string selection lines SSL. In addition, the wordlines WL may include a dummy wordline that is not used for data storage. The dummy wordline may be used for various purposes.

For example, in a manufacturing process of a cell string CS, the width of the pillar PL or the cross-sectional area parallel to the upper surface of the semiconductor substrate SUB may be formed smaller as the distance from the semiconductor substrate SUB decreases. Accordingly, when the same voltage is applied to the bodies of the ground selection transistor GST in FIG. 14, the memory cells MC and the string selection transistors SST and the same voltage is applied to the ground selection line GSL, the wordlines WL and the string selection lines SSL, an electric field formed in the memory cell or the ground selection transistor GST adjacent to the semiconductor substrate SUB is larger than an electric field formed in a memory cell or the string selection transistor SST far from the semiconductor substrate SUB. This characteristic affects a disturbance that occurs during a program operation and/or a read operation. The width of the pillar PL or the cross-sectional area parallel to the upper surface of the semiconductor substrate SUB is not limited to the case as illustrated in FIG. 21. In some implementations, the width of the pillar PL or the cross-sectional area parallel to the upper surface of the semiconductor substrate SUB may be formed differently according to the distance from the semiconductor substrate SUB depending on the etching process. In this way, the characteristics of the memory cell may be different depending on the physical position or the height in the vertical direction D3 of the wordline.

The pillar PL corresponds to the channel hole of the cell string, and as shown in FIG. 21, the diameter of the cross-sectional area of the channel hole decreases downward. That is, as shown in FIG. 21, the diameter of the cross-sectional area of the channel hole decreases as a distance from the semiconductor substrate SUB decreases. Therefore, the size of the floating gate of the flash memory cell decreases as it goes downward in the channel hole, and the retention capability of the memory cell decreases. That is, the size of the floating gate of the flash memory cell decreases a distance from the semiconductor substrate SUB in the channel hole decreases. Therefore, the retention capability of the memory cells connected to the wordline WL0 located at the lowest portion of the channel hole may be the smallest, and the retention capability of the memory cells connected to the wordline WLn located at the highest portion of the channel hole may be the largest. On the other hand, the retention capability of the memory cells located at the end of the channel hole may be reduced due to limitations of the manufacturing process, etc. According to the characteristics of such physical structures, the grouping of the wordlines may be performed.

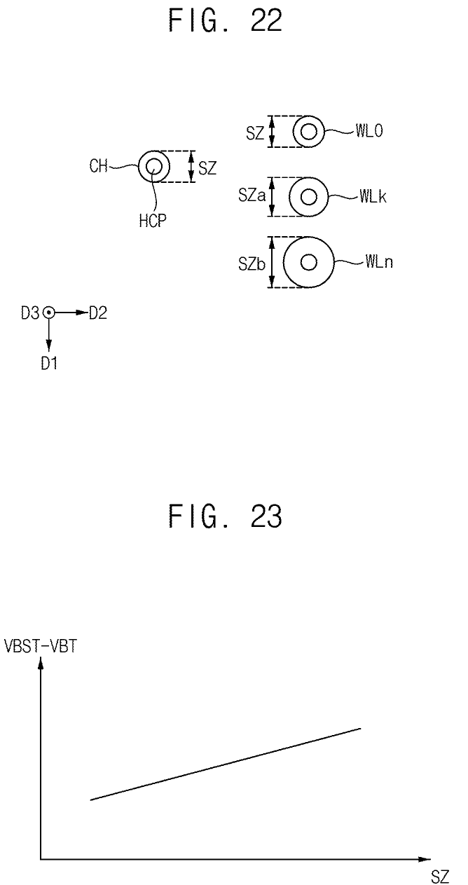

FIG. 22 is a diagram for describing a horizontal cross-sectional size according a height in a cell string, and FIGS. 23, 24 and 25 are diagrams illustrating some implementations of voltage regulation for a back-tunneling electron-injection operation in a nonvolatile memory device according to some implementations.

Referring to FIGS. 21 and 22, the size SZ of a horizontal cross-section of a cell channel structure CH may increase as the corresponding wordline is disposed higher. The size SZa of the horizontal cross-section of the cell channel structure CH corresponding to the wordline WLk at the middle portion may be larger than the size SZ of the horizontal cross-section of the cell channel structure CH corresponding to the wordline WL0 at the bottom portion, and the size SZb of the horizontal cross-section of the cell channel structure CH corresponding to the wordline WLn at the top portion may be larger than the size SZa of the horizontal cross-section of the cell channel structure CH corresponding to the wordline WLk at the middle portion.

As described with reference to FIGS. 21 and 22, if the channel of the plurality of memory cells are formed in a channel hole having a diameter, the size SZ of the horizontal cross-section gradually decreasing downward, the difference VBST-VBT between the boosting voltage VBST and the back-tunneling voltage VBT may increase as the size SZ of the cross-sectional area of the channel hole decreases, as shown in FIG. 23.

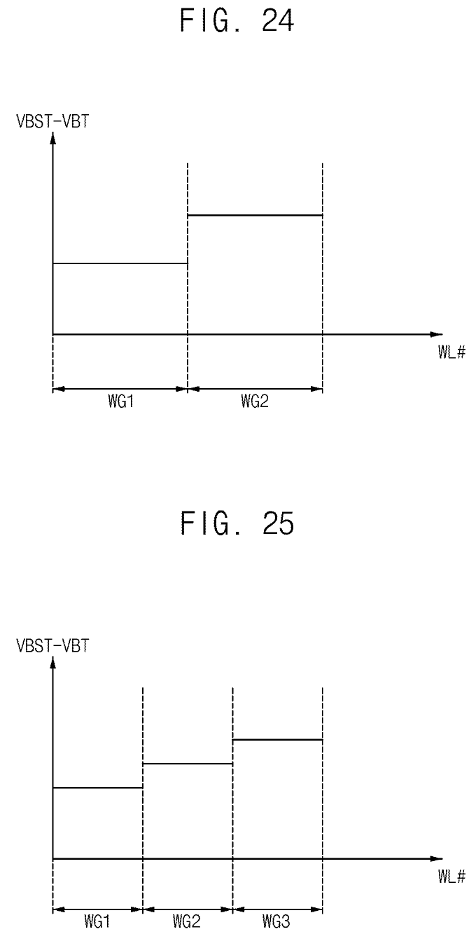

In FIGS. 24 and 25, the horizontal axis indicates a wordline number WL#, and as the wordline number WL# increases, the size SZ of the horizontal cross-section of the channel hole may increase.

Based on the cross-sectional area of the channel hole, the plurality of wordlines may be grouped into a plurality of wordline groups, and the difference VBST-VBT between the boosting voltage VBST and the back-tunneling voltage VBT may be controlled or determined for each wordline group. For example, as shown in FIGS. 24 and 25, the plurality of wordlines may be grouped into two or three wordline groups, and the difference VBST-VBT between the boosting voltage VBST and the back-tunneling voltage VBT may be set for each wordline group.

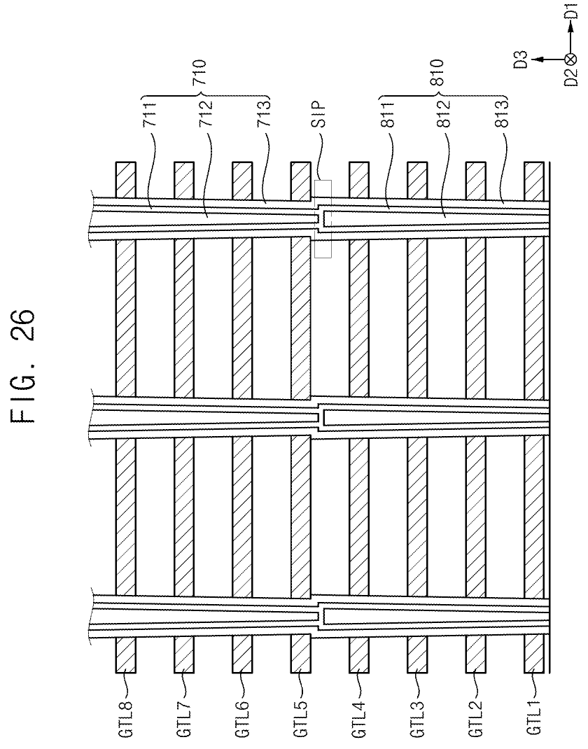

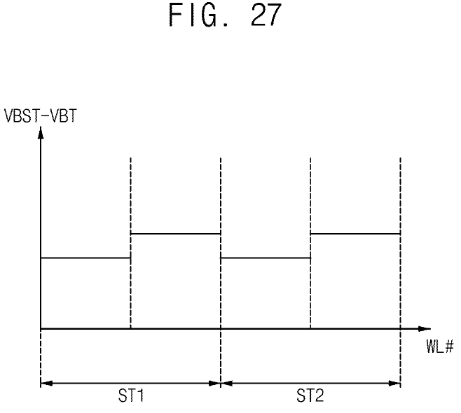

FIG. 26 is a cross-sectional view illustrating some implementations of a sub-stack division of a nonvolatile memory device according to some implementations, and FIG. 27 is a diagram illustrating some implementations of voltage regulation for a back-tunneling electron-injection operation of a nonvolatile memory device according to some implementations.

Referring to FIG. 26, each channel hole forming each cell string may include a first sub-channel hole 810 and a second sub-channel hole 710. The first sub-channel hole 810 may include a channel 811, an inner material 812, and an insulating layer 813. The second sub-channel hole 710 may include a channel 711, an inner material 712, and an insulating layer 713. The channel 811 of the first sub-channel hole 810 and the channel 711 of the second sub-channel hole 710 may be connected via a P-type silicon pad.

The plurality of sub-channel holes 810 and 710 may be formed using a stopper line GTL5 having a suitable etch selectivity ratio. For example, to implement the suitable etch selectivity, the stopper line GTL5 may be formed of polysilicon and the remaining gate lines GTL1 to GTL4, and GTL6 to GTL8 may be formed of a metal such as tungsten. Although there is dependency on the doping concentration of the polysilicon, the resistance value of the stopper line GTL5 is significantly larger than the respective resistance values of the remaining gate lines GTL1 to GTL4, and GTL6 to GTL8, by about six times.

An example where each channel hole includes two sub-channel holes has been described with reference to FIG. 26, but implementations are not limited thereto. According to some implementations, each channel hole may include three or more sub-channel holes stacked in the vertical direction D3.

As shown in FIG. 27, for each of the first sub-stack SB1 corresponding to the first sub-channel hole 810 and the second sub-stack SB2 corresponding to the second sub-channel hole 710, wordlines may be grouped and the difference VBST-VBT between the boosting voltage VBST and the back-tunneling voltage VBT may be set for each group of wordlines.

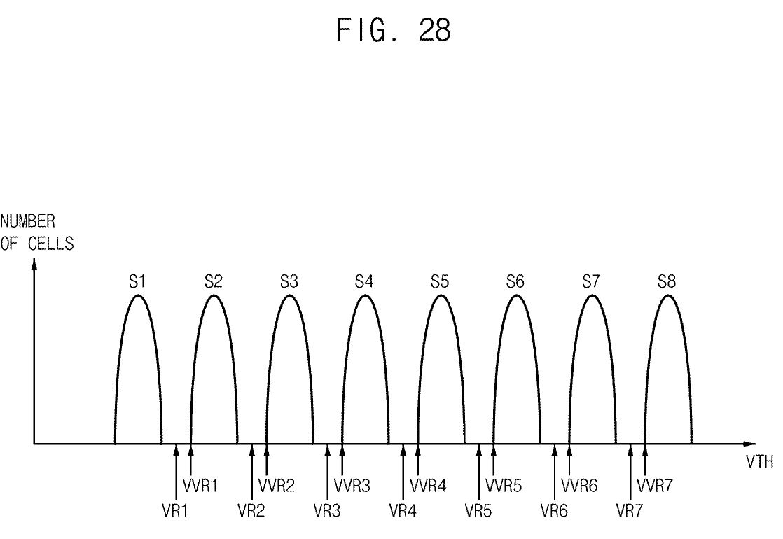

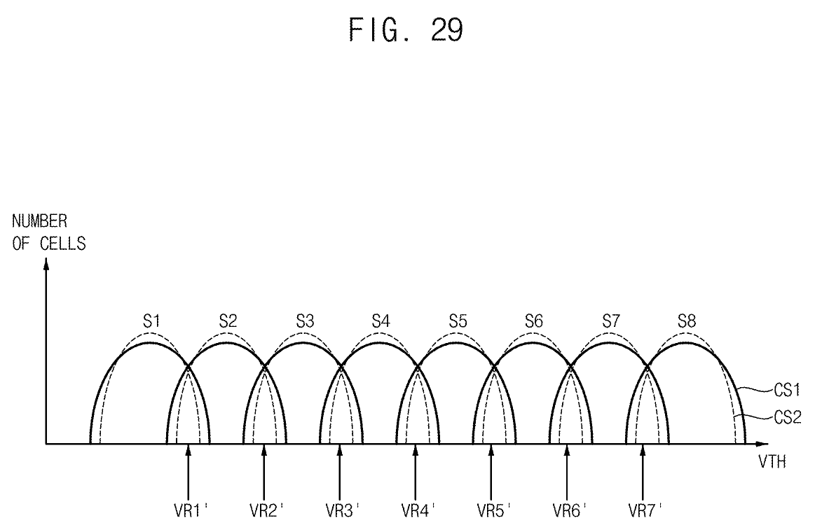

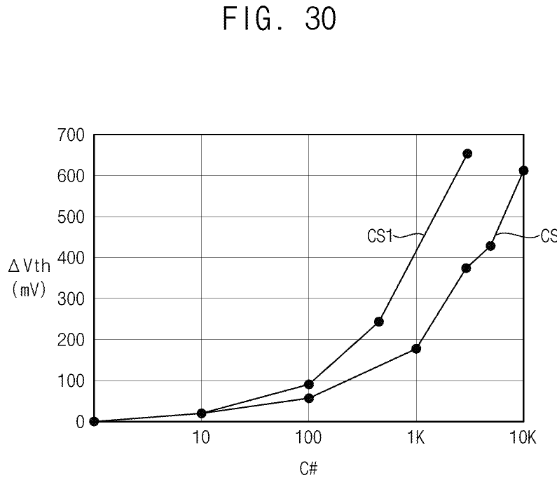

FIG. 28 is a diagram illustrating example states of multi-level cells included in a nonvolatile memory device according to some implementations, and FIGS. 29 and 30 are diagrams for describing effects of a method of operating a nonvolatile memory device according to some implementations.

FIG. 28 illustrates first through eighth states S1~S8 of a triple level cell (TLC) memory where each memory cell of the TLC memory may store three data bits. In FIG. 28, the horizontal axis represents a threshold voltage VTH of memory cells and the vertical axis represents the number of the memory cells corresponding to the threshold voltage VTH. During the program operation, the program success of the first through eighth states S1~S8 may be distinguished by respectively applying first through seventh verification read voltages VVR1~VVR7 to the selected wordline. During the read operation, the first through eighth states S1~S8 of each memory cell may be determined by respectively applying first through seventh read voltages VR1~VR7 to the selected wordline.

FIG. 29 shows degraded states of the TLC memory of FIG. 28.

The threshold voltage distributions of FIG. 28 for the states S1~S8 may degrade to the threshold voltage distributions shown in FIG. 29 due to various factors. During or after the memory cells are programmed to have the threshold voltage distributions of FIG. 28, each threshold voltage distribution may be distorted by changes in the operating environment, such as charge leakage, self-discharge disturbance, programmed disturbance, coupling, temperature changes, voltage changes, and degradation of the memory cells due to repeated programming and erasing. For example, the threshold voltage distributions may be broadened or shifted.

As such, depending on the extent to which the threshold voltage distributions are degraded, an read operation based on the predetermined read voltages VR1~VR7 of FIG. 28 may cause read failure. Therefore, a data recovery read operation may be performed in which optimal extraction voltages VR1'~VR7' as shown in FIG. 29 are obtained and a read operation is performed again based on the optimal read voltages VR1'~VR7'. However, in the case of a severe degree of degradation, it may not be possible to determine the states S1~S8 even by the optimal read voltages VR1'~VR7'.

In FIGS. 29 and 30, a first case CS1 shows results according to the method of U.S. Registered Patent US9,734,913 and a second case CS2 shows results according to some implementations. In FIG. 30, the horizontal axis represents a program-erase cycle (C#) and the vertical axis represents a threshold voltage variation ΔVth of a memory cell.

As shown in FIG. 29, it may be seen that the threshold voltage distribution CS2 of the memory cells according to some implementations has a smaller degree of degradation than the threshold voltage distribution CS1 of the conventional memory cells. Furthermore, as shown in FIG. 30, it may be seen that for the same program-erase cycle C#, the threshold voltage variation CS2 of the memory cells according to some implementations is smaller than the threshold voltage variation CS1 of the conventional memory cells.

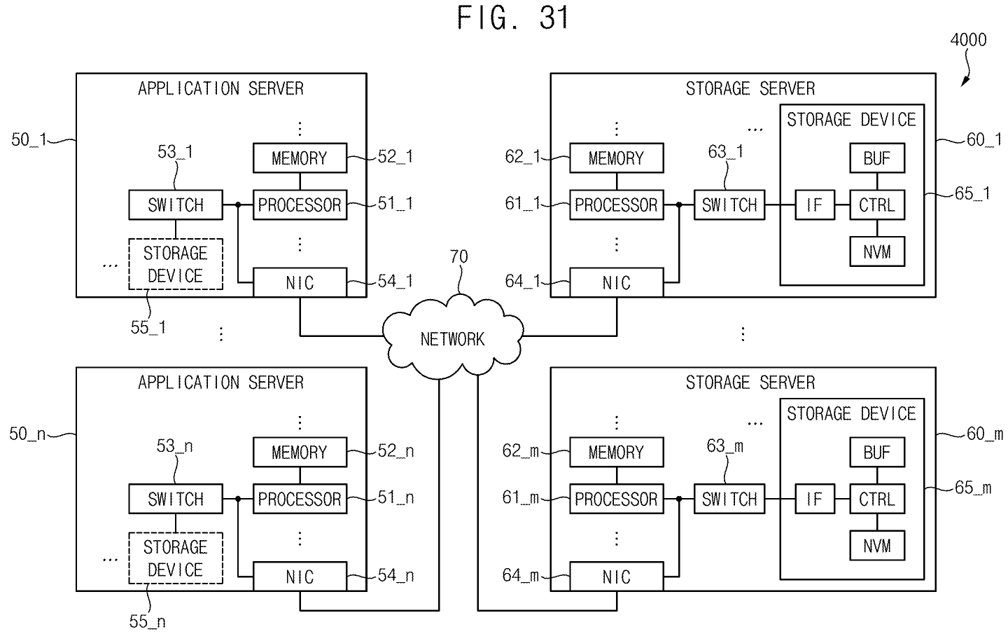

FIG. 31 is a block diagram illustrating a data center including a storage device according to some implementations.

In some implementations, the storage device described above with reference to FIGS. 1 through 30 may serve as an application server and/or a storage server and may be included in a data center 4000.

Referring to FIG. 31, the data center 4000 may collect various pieces of data and provide services and be also referred to as a data storage center. For example, the data center 4000 may be a system configured to operate a search engine and a database or a computing system used by companies, such as banks, or government agencies. As shown in FIG. 31, the data center 4000 may include application servers 50_1 to 50_n and storage servers 60_1 to 60_m (where, each of m and n is an integer more than 1). The number n of application servers 50_1 to 50_n and the number m of storage servers 60_1 to 60_m may be variously selected according to some implementations. In some implementations, the number n of application servers 50_1 to 50_n may be different from the number m of storage servers 60_1 to 60_m.

The application servers 50_1 to 50_n may include any one or any combination of processors 51_1 to 51_n, memories 52_1 to 52_n, switches 53_1 to 53_n, network interface controllers (NICs) 54_1 to 54_n, and storage devices 55_1 to 55_n. The processors 51_1 to 51_n may control all operations of the application servers 50_1 to 50_n, access the memories 52_1 to 52_n, and execute instructions and/or data loaded in the memories 52_1 to 52_n. Non-limiting examples of the memories 52_1 to 52_n may include DDR SDRAM, a high-bandwidth memory (HBM), a hybrid memory cube (HMC), a dual in-line memory module (DIMM), a Optane DIMM, and/or a nonvolatile DIMM (NVDIIMM).

According to some implementations, the numbers of processors and memories included in the application servers 50_1 to 50_n may be variously selected according to some implementations. In some implementations, the processors 51_1 to 51_n and the memories 52_1 to 52_n may provide processor-memory pairs. In some implementations, the number of processors 51_1 to 51_n may be different from the number of memories 52_1 to 52_n. The processors 51_1 to 51_n may include a single core processor or a multi-core processor. In some implementations, as illustrated with a dashed line in FIG. 31, the storage devices 55_1 to 55_n may be omitted from the application servers 50_1 to 50_n. The number of storage devices 55_1 to 55_n included in the storage servers 50_1 to 50_n may be variously selected according to some implementations. The processors 51_1 to 51_n, the memories 52_1 to 52_n, the switches 53_1 to 53_n, the NICs 54_1 to 54_n, and/or the storage devices 55_1 to 55_n may communicate with each other through a link described above with reference to the drawings.

The storage servers 60_1 to 60_m may include any one or any combination of processors 61_1 to 61_m, memories 62_1 to 62_m, switches 63_1 to 63_m, network interface controllers (NICs) 64_1 to 64_n, and storage devices 65_1 to 65_m. The processors 61_1 to 61_m and the memories 62_1 to 62_m may operate similar to the processors 51_1 to 51_n and the memories 52_1 to 52_n of the application servers 50_1 to 50_n described above.

The application servers 50_1 to 50_n may communicate with the storage servers 60_1 to 60_m through a network 70. In some implementations, the network 70 may be implemented using a fiber channel (FC) or Ethernet. The FC may be a medium used for relatively high-speed data transfer. An optical switch that provides high performance and high availability may be used as the FC. The storage servers 60_1 to 60_m may be provided as file storages, block storages, or object storages according to an access method of the network 70.

In some implementations, the network 70 may be a storage-only network, such as a storage area network (SAN). For example, the SAN may be an FC-SAN, which may use an FC network and be implemented using an FC Protocol (FCP). In another case, the SAN may be an Internet protocol (IP)-SAN, which uses a transmission control protocol/Internet protocol (TCP/IP) network and is implemented according to an SCSI over TCP/IP or Internet SCSI (iSCSI) protocol. In some implementations, the network 70 may be a general network, such as a TCP/IP network. For example, the network 70 may be implemented according to a protocol, such as FC over Ethernet (FCoE), network attached storage (NAS), nonvolatile memory express (NVMe) over fabrics (NVMe-oF).

The application server 50_1 and the storage server 60_1 will mainly be described, but it may be noted that a description of the application server 50_1 may be also applied to another application server (e.g., 50_n), and a description of the storage server 60_1 may be also applied to another storage server (e.g., 60_m).

The application server 50_1 may store data, which is requested to be stored by a user or a client, in one of the storage servers 60_1 to 60_m through the network 70. In some implementations, the application server 50_1 may obtain data, which is requested to be read by the user or the client, from one of the storage servers 60_1 to 60_m through the network 70. For example, the application server 50_1 may be implemented using a web server or a database management system (DBMS).

The application server 50_1 may access the memory 52_n and/or the storage device 55_n included in another application server 50_n, through the network 70, and/or access the memories 62_1 to 62_m and/or the storage devices 65_1 to 65_m included in the storage servers 60_1 to 60_m, through the network 70. Accordingly, the application server 50_1 may perform various operations on data stored in the application servers 50_1 to 50_n and/or the storage servers 60_1 to 60_m. For example, the application server 50_1 may execute an instruction to migrate or copy data between the application servers 50_1 to 50_n and/or the storage servers 60_1 to 60_m. In this case, the data may be migrated from the storage devices 65_1 to 65_m of the storage servers 60_1 to 60_m to the memories 52_1 to 52_n of the application servers 50_1 to 50_n through the memories 62_1 to 62_m of the storage servers 60_1 to 60_m or directly. In some implementations, the data migrated through the network 70 may be encrypted data for security or privacy.

In the storage server 60_1, an interface IF may provide physical connection between the processor 61_1 and a controller CTRL and physical connection between the NIC 64_1 and the controller CTRL. For example, the interface IF may be implemented using a direct attached storage (DAS) method in which the storage device 65_1 is directly connected to a dedicated cable. For example, the interface IF may be implemented using various interface methods, such as advanced technology attachment (ATA), serial ATA (SATA), external SATA (e-SATA), small computer small interface (SCSI), serial attached SCSI (SAS), PCI, PCIe, NVMe, IEEE 1394, a universal serial bus (USB), a secure digital (SD) card, a multi-media card (MMC), an embedded MMC (eMMC), a UFS, an embedded UFS (eUFS), and/or a compact flash (CF) card interface.

In the storage server 60_1, the switch 63_1 may selectively connect the processor 61_1 to the storage device 65_1 or selectively connect the NIC 64_1 to the storage device 65_1 based on the control of the processor 61_1.

In some implementations, the network interface controller (NIC) 64_1 may include a network interface card and a network adaptor. The NIC 54_1 may be connected to the network 70 through a wired interface, a wireless interface, a Bluetooth interface, or an optical interface. The NIC 54_1 may include an internal memory, a digital signal processor (DSP), and a host bus interface and be connected to the processor 61_1 and/or the switch 63_1 through the host bus interface. In some implementations, the NIC 64_1 may be integrated with any one or any combination of the processor 61_1, the switch 63_1, and the storage device 65_1.

In the application servers 50_1 to 50_n or the storage servers 60_1 to 60_m, the processors 51_1 to 51_m and 61_1 to 61_n may transmit commands to the storage devices 55_1 to 55_n and 65_1 to 65_m or the memories 52_1 to 52_n and 62_1 to 62_m and program or read data. In this case, the data may be data of which an error is corrected by an error correction code (ECC) engine. The data may be data processed with data bus inversion (DBI) or data masking (DM) and include cyclic redundancy Code (CRC) information. The data may be encrypted data for security or privacy.

In response to read commands received from the processors 51_1 to 51_m and 61_1 to 61_n, the storage devices 55_1 to 55_n and 65_1 to 65_m may transmit control signals and command/address signals to a nonvolatile memory device (e.g., a NAND flash memory device) NVM. Accordingly, when data is read from the nonvolatile memory device NVM, a read enable signal may be input as a data output control signal to output the data to a DQ bus. A data strobe signal may be generated using the read enable signal. The command and the address signal may be latched according to a rising edge or falling edge of a write enable signal.

The controller CTRL may control all operations of the storage device 65_1. In some implementations, the controller CTRL may include static RAM (SRAM). The controller CTRL may write data to the nonvolatile memory device NVM in response to a write command or read data from the nonvolatile memory device NVM in response to a read command. For example, the write command and/or the read command may be generated based on a request provided from a host (e.g., the processor 61_1 of the storage server 60_1, the processor 61_m of another storage server 60_m, or the processors 51_1 to 51_n of the application servers 50_1 to 50_n). A buffer BUF may temporarily store (or buffer) data to be written to the nonvolatile memory device NVM or data read from the nonvolatile memory device NVM. In some implementations, the buffer BUF may include DRAM. The buffer BUF may store metadata. The metadata may refer to user data or data generated by the controller CTRL to manage the nonvolatile memory device NVM. The storage device 65_1 may include a secure element (SE) for security or privacy.

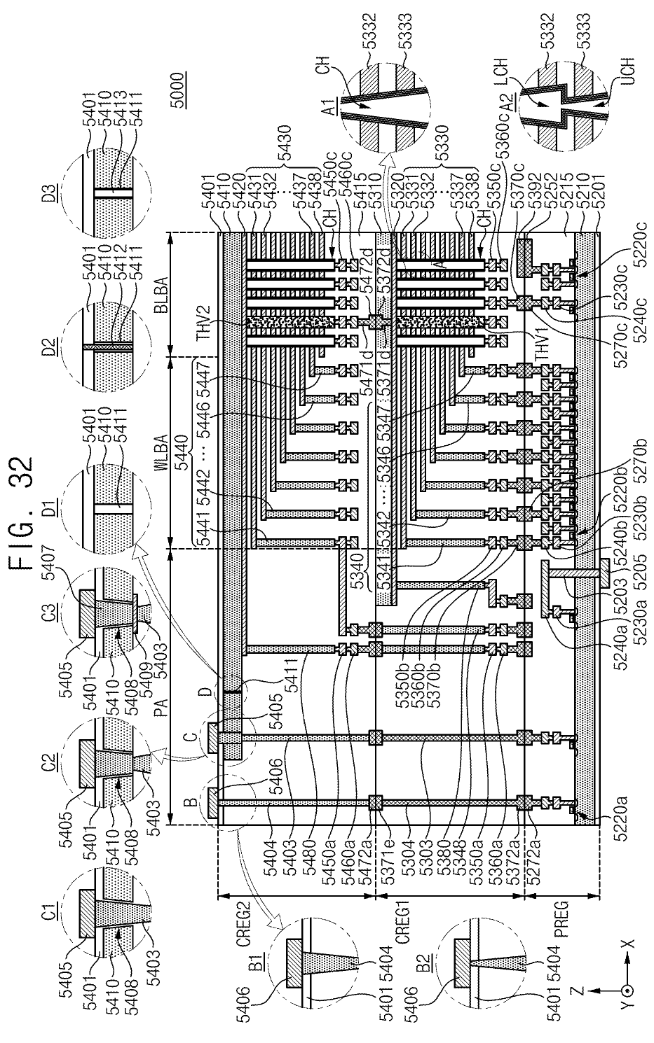

FIG. 32 is a cross-section diagram illustrating a nonvolatile memory device according to some implementations.

Referring to FIG. 32, the memory device 5000 may have a chip-to-chip (C2C) structure. At least one upper chip including a cell region and a lower chip including a peripheral circuit region PREG may be manufactured separately, and then, the at least one upper chip and the lower chip may be connected to each other by a bonding method to realize the C2C structure. For example, the bonding method may refer to a method of electrically and/or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu-Cu bonding method. Alternatively or additionally, the bonding metal patterns may be formed of other metals including, but not being limited to, aluminum (Al) or tungsten (W).

The memory device 5000 may include the at least one upper chip including the cell region. For example, as shown in FIG. 32, the memory device 5000 may include two upper chips. However, the number of the upper chips is not limited thereto. In the case in which the memory device 5000 includes the two upper chips, a first upper chip that may include a first cell region CREG1, a second upper chip that may include a second cell region CREG2 and the lower chip that may include the peripheral circuit region PREG, may be manufactured separately. Subsequently, the first upper chip, the second upper chip and the lower chip may be connected to each other by the bonding method to manufacture the memory device 5000, for example. In some implementations, the first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a -Z-axis direction in FIG. 32. However, the implementations are not limited in this regard. For example, in some implementations, one of the first upper chip and the second upper chip may be turned over and then may be connected to a corresponding chip by the bonding method.

Each of the peripheral circuit region PREG and the first and second cell regions CREG1 and CREG2 of the memory device 5000 may include an external pad bonding region PA, a wordline bonding region WLBA, and a bitline bonding region BLBA.

The peripheral circuit region PREG may include a first substrate 5210 and a plurality of circuit elements (e.g., first circuit element 5220a, second circuit element 5220b, and third circuit element 5220c) formed on the first substrate 5210. An interlayer insulation layer 5215 including one or more insulation layers may be provided on the plurality of circuit elements 5220a, 5220b and 5220c, and a plurality of metal lines electrically connected to the plurality of circuit elements 5220a, 5220b and 5220c may be provided in the interlayer insulation layer 5215. For example, the plurality of metal lines may include first metal lines 5230a, 5230b and 5230c connected to the plurality of circuit elements 5220a, 5220b and 5220c, and second metal lines 5240a, 5240b and 5240c formed on the first metal lines 5230a, 5230b and 5230c. The plurality of metal lines may be formed of at least one of various conductive materials. In some implementations, the first metal lines 5230a, 5230b and 5230c may be formed of tungsten having a relatively high electrical resistivity, and the second metal lines 5240a, 5240b and 5240c may be formed of copper having a relatively low electrical resistivity.

The first metal lines 5230a, 5230b and 5230c and the second metal lines 5240a, 5240b and 5240c are illustrated and described in some implementations. However, the present disclosure is not limited in this regard. For example, in some implementations, at least one or more additional metal lines may further be formed on the second metal lines 5240a, 5240b and 5240c. In this case, the second metal lines 5240a, 5240b and 5240c may be formed of aluminum, and at least some of the additional metal lines formed on the second metal lines 5240a, 5240b and 5240c may be formed of copper having an electrical resistivity lower than that of aluminum of the second metal lines 5240a, 5240b and 5240c.

The interlayer insulation layer 5215 may be disposed on the first substrate 5210 and may include an insulating material such as silicon oxide and/or silicon nitride.

Each of the first and second cell regions CREG1 and CREG2 may include at least one memory block. The first cell region CREG1 may include a second substrate 5310 and a common source line 5320. A plurality of wordlines 5330 (e.g., 5331 to 5338) may be stacked on the second substrate 5310 in a direction (e.g., the Z-axis direction) perpendicular to a top surface of the second substrate 5310. String selection lines and a ground selection line may be disposed on and under the wordlines 5330, and the plurality of wordlines 5330 may be disposed between the string selection lines and the ground selection line. Alternatively, or additionally, the second cell region CREG2 may include a third substrate 5410 and a common source line 5420, and a plurality of wordlines 5430 (e.g., 5431 to 5438) may be stacked on the third substrate 5410 in a direction (e.g., the Z-axis direction) perpendicular to a top surface of the third substrate 5410. Each of the second substrate 5310 and the third substrate 5410 may be formed of at least one of various materials, such as, but not limited to, a silicon substrate, a silicon-germanium substrate, a germanium substrate, or a substrate having a single-crystalline epitaxial layer grown on a single-crystalline silicon substrate. A plurality of cell channel structures CH may be formed in each of the first and second cell regions CREG1 and CREG2.

In some implementations, as illustrated in a region ‘A1’, the cell channel structure CH may be provided in the bitline bonding region BLBA and may extend in the direction perpendicular to the top surface of the second substrate 5310 to penetrate the wordlines 5330, the string selection lines, and the ground selection line. The cell channel structure CH may include a data storage layer, a channel layer, and a filling insulation layer. The channel layer may be electrically connected to a first metal line 5350c and a second metal line 5360c in the bitline bonding region BLBA. For example, the second metal line 5360c may be a bitline and may be connected to the cell channel structure CH through the first metal line 5350c. The bitline 5360c may extend in a first direction (e.g., a Y-axis direction) parallel to the top surface of the second substrate 5310.

In some implementations, as illustrated in a region ‘A2’, the cell channel structure CH may include a lower channel LCH and an upper channel UCH, which may be connected to each other. For example, the cell channel structure CH may be formed by a process of forming the lower channel LCH and a process of forming the upper channel UCH. The lower channel LCH may extend in the direction perpendicular to the top surface of the second substrate 5310 to penetrate the common source line 5320 and lower wordlines 5331 and 5332. The lower channel LCH may include a data storage layer, a channel layer, and a filling insulation layer and may be connected to the upper channel UCH. The upper channel UCH may penetrate upper wordlines 5333 to 5338. The upper channel UCH may include a data storage layer, a channel layer, and a filling insulation layer, and the channel layer of the upper channel UCH may be electrically connected to the first metal line 5350c and the second metal line 5360c. As a length of the channel increases, due to characteristics of manufacturing processes, it may be difficult to form a channel having a substantially uniform width. The memory device 5000, according to the present disclosure, may include a channel having improved width uniformity due to the lower channel LCH and the upper channel UCH which are formed by the processes performed sequentially.

In the case in which the cell channel structure CH includes the lower channel LCH and the upper channel UCH as illustrated in the region ‘A2’, a wordline located near to a boundary between the lower channel LCH and the upper channel UCH may be a dummy wordline. For example, the wordlines 5332 and 5333 adjacent to the boundary between the lower channel LCH and the upper channel UCH may be the dummy wordlines. In this case, data may not be stored in memory cells connected to the dummy wordline. Alternatively, or additionally, the number of pages corresponding to the memory cells connected to the dummy wordline may be less than the number of pages corresponding to the memory cells connected to a general wordline. A level of a voltage applied to the dummy wordline may be different from a level of a voltage applied to the general wordline, and thus, it may be possible to reduce an influence of a non-uniform channel width between the lower and upper channels LCH and UCH on an operation of the memory device.

In some implementations, the number of the lower wordlines 5331 and 5332 penetrated by the lower channel LCH may be less than the number of the upper wordlines 5333 to 5338 penetrated by the upper channel UCH in the region ‘A2’. However, the present disclosure is not limited in this regard. For example, in some implementations, the number of the lower wordlines penetrated by the lower channel LCH may be equal to or more than the number of the upper wordlines penetrated by the upper channel UCH. Alternatively, or additionally, structural features and connection relation of the cell channel structure CH disposed in the second cell region CREG2 may be substantially the same as those of the cell channel structure CH disposed in the first cell region CREG1.

In the bitline bonding region BLBA, a first through-electrode THV1 may be provided in the first cell region CREG1, and a second through-electrode THV2 may be provided in the second cell region CREG2. As illustrated in FIG. 32, the first through-electrode THV1 may penetrate the common source line 5320 and the plurality of wordlines 5330. In some implementations, the first through-electrode THV1 may further penetrate the second substrate 5310. The first through-electrode THV1 may include a conductive material. Alternatively, or additionally, the first through-electrode THV1 may include a conductive material surrounded by an insulating material. The second through-electrode THV2 may have the same shape and structure as the first through-electrode THV1.

In some implementations, the first through-electrode THV1 and the second through-electrode THV2 may be electrically connected to each other through a first through-metal pattern 5372d and a second through-metal pattern 5472d. The first through-metal pattern 5372d may be formed at a bottom end of the first upper chip including the first cell region CREG1, and the second through-metal pattern 5472d may be formed at a top end of the second upper chip including the second cell region CREG2. The first through-electrode THV1 may be electrically connected to the first metal line 5350c and the second metal line 5360c. A lower via 5371d may be formed between the first through-electrode THV1 and the first through-metal pattern 5372d, and an upper via 5471d may be formed between the second through-electrode THV2 and the second through-metal pattern 5472d. The first through-metal pattern 5372d and the second through-metal pattern 5472d may be connected to each other by the bonding method.

In some implementations, in the bitline bonding region BLBA, an upper metal pattern 5252 may be formed in an uppermost metal layer of the peripheral circuit region PERI, and an upper metal pattern 5392 having the same shape as the upper metal pattern 5252 may be formed in an uppermost metal layer of the first cell region CREG1. The upper metal pattern 5392 of the first cell region CREG1 and the upper metal pattern 5252 of the peripheral circuit region PREG may be electrically connected to each other by the bonding method. In the bitline bonding region BLBA, the bitline 5360c may be electrically connected to a page buffer included in the peripheral circuit region PERI. For example, some of the circuit elements 5220c of the peripheral circuit region PREG may constitute the page buffer, and the bitline 5360c may be electrically connected to the circuit elements 5220c constituting the page buffer through an upper bonding metal pattern 5370c of the first cell region CREG1 and an upper bonding metal pattern 5270c of the peripheral circuit region PERI.

Continuing to refer to FIG. 32, in the wordline bonding region WLBA, the wordlines 5330 of the first cell region CREG1 may extend in a second direction (e.g., an X-axis direction) parallel to the top surface of the second substrate 5310 and may be connected to a plurality of cell contact plugs 5340 (e.g., 5341 to 5347). First metal lines 5350b and second metal lines 5360b may be sequentially connected onto the cell contact plugs 5340 connected to the wordlines 5330. In the wordline bonding region WLBA, the cell contact plugs 5340 may be connected to the peripheral circuit region PREG through upper bonding metal patterns 5370b of the first cell region CREG1 and upper bonding metal patterns 5270b of the peripheral circuit region PERI.

The cell contact plugs 5340 may be electrically connected to a row decoder included in the peripheral circuit region PERI. For example, some of the circuit elements 5220b of the peripheral circuit region PREG may constitute the row decoder, and the cell contact plugs 5340 may be electrically connected to the circuit elements 5220b constituting the row decoder through the upper bonding metal patterns 5370b of the first cell region CREG1 and the upper bonding metal patterns 5270b of the peripheral circuit region PERI. In some implementations, an operating voltage of the circuit elements 5220b constituting the row decoder may be different from an operating voltage of the circuit elements 5220c constituting the page buffer. For example, the operating voltage of the circuit elements 5220c constituting the page buffer may be greater than the operating voltage of the circuit elements 5220b constituting the row decoder.

In some implementations, in the wordline bonding region WLBA, the wordlines 5430 of the second cell region CREG2 may extend in the second direction (e.g., the X-axis direction) parallel to the top surface of the third substrate 5410 and may be connected to a plurality of cell contact plugs 5440 (e.g., 5441 to 5447). The cell contact plugs 5440 may be connected to the peripheral circuit region PREG through an upper metal pattern of the second cell region CREG2 and lower and upper metal patterns and a cell contact plug 5348 of the first cell region CREG1.

In the wordline bonding region WLBA, the upper bonding metal patterns 5370b may be formed in the first cell region CREG1, and the upper bonding metal patterns 5270b may be formed in the peripheral circuit region PERI. The upper bonding metal patterns 5370b of the first cell region CREG1 and the upper bonding metal patterns 5270b of the peripheral circuit region PREG may be electrically connected to each other by the bonding method. The upper bonding metal patterns 5370b and the upper bonding metal patterns 5270b may be formed of at least one metal including, but not limited to, aluminum, copper, and tungsten.

In the external pad bonding region PA, a lower metal pattern 5371e may be formed in a lower portion of the first cell region CREG1, and an upper metal pattern 5472a may be formed in an upper portion of the second cell region CREG2. The lower metal pattern 5371e of the first cell region CREG1 and the upper metal pattern 5472a of the second cell region CREG2 may be connected to each other by the bonding method in the external pad bonding region PA. In some implementations, an upper metal pattern 5372a may be formed in an upper portion of the first cell region CREG1, and an upper metal pattern 5272a may be formed in an upper portion of the peripheral circuit region PERI. The upper metal pattern 5372a of the first cell region CREG1 and the upper metal pattern 5272a of the peripheral circuit region PREG may be connected to each other by the bonding method.

Common source line contact plugs 5380 and 5480 may be disposed in the external pad bonding region PA. The common source line contact plugs 5380 and 5480 may be formed of a conductive material such as a metal, a metal compound, and/or doped polysilicon. The common source line contact plug 5380 of the first cell region CREG1 may be electrically connected to the common source line 5320, and the common source line contact plug 5480 of the second cell region CREG2 may be electrically connected to the common source line 5420. A first metal line 5350a and a second metal line 5360a may be sequentially stacked on the common source line contact plug 5380 of the first cell region CREG1, and a first metal line 5450a and a second metal line 5460a may be sequentially stacked on the common source line contact plug 5480 of the second cell region CREG2.

Input/output pads 5205, 5405 and 5406 may be disposed in the external pad bonding region PA. As shown in FIG. 32, a lower insulation layer 5201 may cover a bottom surface of the first substrate 5210, and a first input/output pad 5205 may be formed on the lower insulation layer 5201. The first input/output pad 5205 may be connected to at least one of a plurality of the circuit elements 5220a disposed in the peripheral circuit region PREG through a first input/output contact plug 5203 and may be separated from the first substrate 5210 by the lower insulation layer 5201. Alternatively, or additionally, a side insulation layer may be disposed between the first input/output contact plug 5203 and the first substrate 5210 to electrically isolate the first input/output contact plug 5203 from the first substrate 5210.

An upper insulation layer 5401 covering a top surface of the third substrate 5410 may be formed on the third substrate 5410. A second input/output pad 5405 and/or a third input/output pad 5406 may be disposed on the upper insulation layer 5401. The second input/output pad 5405 may be connected to at least one of the pluralities of circuit elements 5220a disposed in the peripheral circuit region PREG through second input/output contact plugs 5403 and 5303, and the third input/output pad 5406 may be connected to at least one of the pluralities of circuit elements 5220a disposed in the peripheral circuit region PREG through third input/output contact plugs 5404 and 5304.

In some implementations, the third substrate 5410 may not be disposed in a region in which the input/output contact plug is disposed. For example, as illustrated in a region ‘B’, the third input/output contact plug 5404 may be separated from the third substrate 5410 in a direction parallel to the top surface of the third substrate 5410 and may penetrate an interlayer insulation layer 5415 of the second cell region CREG2 so as to be connected to the third input/output pad 5406. In this case, the third input/output contact plug 5404 may be formed by at least one of various processes.

In some implementations, as illustrated in a region ‘B1’, the third input/output contact plug 5404 may extend in a third direction (e.g., the Z-axis direction), and a diameter of the third input/output contact plug 5404 may become progressively greater (e.g., wider) toward the upper insulation layer 5401. In other words, a diameter of the cell channel structure CH described in the region ‘A1’ may become progressively less (e.g., narrower) toward the upper insulation layer 5401, but the diameter of the third input/output contact plug 5404 may become progressively greater toward the upper insulation layer 5401. For example, the third input/output contact plug 5404 may be formed after the second cell region CREG2 and the first cell region CREG1 are bonded to each other by the bonding method.

In some implementations, as illustrated in a region ‘B2’, the third input/output contact plug 5404 may extend in the third direction (e.g., the Z-axis direction), and a diameter of the third input/output contact plug 5404 may become progressively less (e.g., narrower) toward the upper insulation layer 5401. In other words, like the cell channel structure CH, the diameter of the third input/output contact plug 5404 may become progressively less (e.g., narrower) toward the upper insulation layer 5401. For example, the third input/output contact plug 5404 may be formed together with the cell contact plugs 5440 before the second cell region CREG2 and the first cell region CREG1 are bonded to each other.

In some implementations, the input/output contact plug may overlap with the third substrate 5410. For example, as illustrated in a region ‘C’, the second input/output contact plug 5403 may penetrate the interlayer insulation layer 5415 of the second cell region CREG2 in the third direction (e.g., the Z-axis direction) and may be electrically connected to the second input/output pad 5405 through the third substrate 5410. In this case, a connection structure of the second input/output contact plug 5403 and the second input/output pad 5405 may be realized by various methods.

In some implementations, as illustrated in a region ‘C1’, an opening 5408 may be formed to penetrate the third substrate 5410, and the second input/output contact plug 5403 may be connected directly to the second input/output pad 5405 through the opening 5408 formed in the third substrate 5410. In this case, as illustrated in the region ‘C1’, a diameter of the second input/output contact plug 5403 may become progressively greater (e.g., wider) toward the second input/output pad 5405. However, the present disclosure is not limited in this regard. For example, in some implementations, the diameter of the second input/output contact plug 5403 may become progressively less (e.g., narrower) toward the second input/output pad 5405.

In some implementations, as illustrated in a region ‘C2’, the opening 5408 penetrating the third substrate 5410 may be formed, and a contact 5407 may be formed in the opening 5408. An end of the contact 5407 may be connected to the second input/output pad 5405, and another end of the contact 5407 may be connected to the second input/output contact plug 5403. Thus, the second input/output contact plug 5403 may be electrically connected to the second input/output pad 5405 through the contact 5407 in the opening 5408. In this case, as illustrated in the region ‘C2’, a diameter of the contact 5407 may become progressively greater (e.g., wider) toward the second input/output pad 5405, and a diameter of the second input/output contact plug 5403 may become progressively less (e.g., narrower) toward the second input/output pad 5405. For example, the second input/output contact plug 5403 may be formed together with the cell contact plugs 5440 before the second cell region CREG2 and the first cell region CREG1 are bonded to each other, and the contact 5407 may be formed after the second cell region CREG2 and the first cell region CREG1 are bonded to each other.

In some implementations illustrated in a region ‘C3’, a stopper 5409 may further be formed on a bottom end of the opening 5408 of the third substrate 5410, as compared with the implementations of the region ‘C2’. The stopper 5409 may be a metal line formed in the same layer as the common source line 5420. Alternatively, or additionally, the stopper 5409 may be a metal line formed in the same layer as at least one of the wordlines 5430. The second input/output contact plug 5403 may be electrically connected to the second input/output pad 5405 through the contact 5407 and the stopper 5409.

Similar to the second and third input/output contact plugs 5403 and 5404 of the second cell region CREG2, a diameter of each of the second and third input/output contact plugs 5303 and 5304 of the first cell region CREG1 may become progressively less (e.g., narrower) toward the lower metal pattern 5371e and/or may become progressively greater (e.g., wider) toward the lower metal pattern 5371e.

In some implementations, a slit 5411 may be formed in the third substrate 5410. For example, the slit 5411 may be formed at a certain position of the external pad bonding region PA. For example, as illustrated in a region ‘D’, the slit 5411 may be located between the second input/output pad 5405 and the cell contact plugs 5440 when viewed in a plan view. Alternatively, or additionally, the second input/output pad 5405 may be located between the slit 5411 and the cell contact plugs 5440 when viewed in a plan view.

In some implementations, as illustrated in a region ‘D1’, the slit 5411 may be formed to penetrate the third substrate 5410. For example, the slit 5411 may be used to prevent the third substrate 5410 from being finely cracked when the opening 5408 is formed. However, the present disclosure is not limited in this regard. For example, in some implementations, the slit 5411 may be formed to have a depth ranging from about 60% to about 70% of a thickness of the third substrate 5410.

In some implementations, as illustrated in a region ‘D2’, a conductive material 5412 may be formed in the slit 5411. For example, the conductive material 5412 may be used to discharge a leakage current occurring in driving of the circuit elements in the external pad bonding region PA to the outside. In this case, the conductive material 5412 may be connected to an external ground line.

In some implementations, as illustrated in a region ‘D3’, an insulating material 5413 may be formed in the slit 5411. For example, the insulating material 5413 may be used to electrically isolate the second input/output pad 5405 and the second input/output contact plug 5403 disposed in the external pad bonding region PA from the wordline bonding region WLBA. Since the insulating material 5413 is formed in the slit 5411, it may be possible to prevent a voltage provided through the second input/output pad 5405 from affecting a metal layer disposed on the third substrate 5410 in the wordline bonding region WLBA.

In some implementations, the first to third input/output pads 5205, 5405 and 5406 may be selectively formed. For example, the memory device 5000 may be realized to include only the first input/output pad 5205 disposed on the first substrate 5210, to include only the second input/output pad 5405 disposed on the third substrate 5410, and/or to include only the third input/output pad 5406 disposed on the upper insulation layer 5401.

In some implementations, at least one of the second substrate 5310 of the first cell region CREG1 and the third substrate 5410 of the second cell region CREG2 may be used as a sacrificial substrate and may be completely and/or partially removed before and/or after a bonding process. An additional layer may be stacked after the removal of the substrate. For example, the second substrate 5310 of the first cell region CREG1 may be removed before and/or after the bonding process of the peripheral circuit region PREG and the first cell region CREG1. Subsequently, an insulation layer covering a top surface of the common source line 5320 or a conductive layer for connection may be formed. Similarly, the third substrate 5410 of the second cell region CREG2 may be removed before and/or after the bonding process of the first cell region CREG1 and the second cell region CREG2, and subsequently, the upper insulation layer 5401 covering a top surface of the common source line 5420 or a conductive layer for connection may be formed.

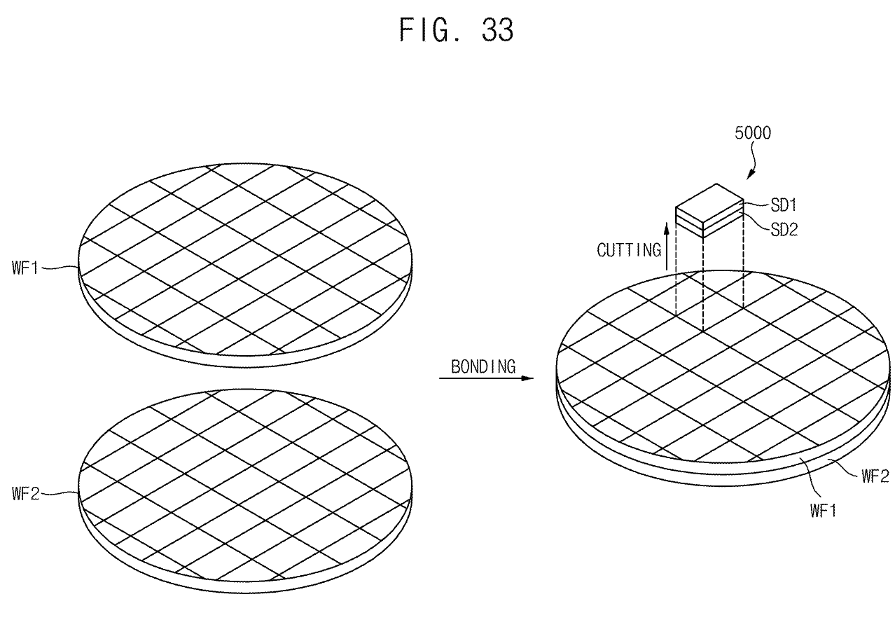

FIG. 33 is a diagram for describing manufacturing processes of a stacked semiconductor device according to some implementations.

Referring to FIG. 33, respective integrated circuits may be formed on a first wafer WF1 and a second wafer WF2. The memory cell array may be formed in the first wafer WF1 and the peripheral circuits may be formed in the second wafer WF2.

After the various integrated circuits have been respectively formed on the first and second wafers WF1 and WF2, the first wafer WF1 and the second wafer WF2 may be bonded together. The bonded wafers WF1 and WF2 may then be cut (or divided) into separate chips, in which each chip corresponds to a semiconductor device such as, for example, the nonvolatile memory device 5000, including a first semiconductor die SD1 and a second semiconductor die SD2 that are stacked vertically (e.g., the first semiconductor die SD1 is stacked on the second semiconductor die SD2, etc.). Each cut portion of the first wafer WF1 corresponds to the first semiconductor die SD1 and each cut portion of the second wafer WF2 corresponds to the second semiconductor die SD2. The memory device of FIG. 32 may be manufactured according to the process of FIG. 33.

As described above, the nonvolatile memory device and the method of operating the nonvolatile memory device according to some implementations may reduce spreading of electrons injected into the charge storage region by injecting electrons into the spacer region to form the potential barrier through the back-tunneling electron-injection operation, thereby improving the data retention characteristics and the reliability of the nonvolatile memory device. The back-tunneling electron-injection operation may reduce performance degradation of the nonvolatile memory device because the back-tunneling electron-injection operation may be performed in a relatively short time, and may reduce degeneration of the memory cells because the back-tunneling electron-injection operation may use the boosting voltage lower than the program voltage and the erase voltage.

In some implementations, a method of operating a nonvolatile memory device includes, performing an erase operation to release electrons in charge storage regions of a plurality of memory cells of the nonvolatile memory device, after performing the erase operation, performing a back-tunneling electron-injection operation to inject electrons into a spacer region between a charge storage region corresponding to a target wordline and a charge storage region corresponding to a neighboring wordline adjacent to the target wordline by applying a back-tunneling voltage to the target wordline and a boosting voltage higher than the back-tunneling voltage to the neighboring wordline, and after performing the back-tunneling electron-injection operation, performing a program operation to inject electrons into the charge storage region corresponding to the target wordline.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The various implementations may be applied to any electronic devices and systems including a nonvolatile memory device. For example, the various implementations may be applied to systems such as a memory card, a solid state drive (SSD), an embedded multimedia card (eMMC), a universal flash storage (UFS), a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, a server system, an automotive driving system, a data center, etc.

The foregoing is illustrative of various implementations and is not to be construed as limiting thereof. Those skilled in the art may readily appreciate that many modifications are possible in the example implementations without materially departing from the scope as defined by the appended claims.

What is claimed is:

1. A method of operating a nonvolatile memory device, comprising:
performing an erase operation to release a first set of electrons at a plurality of charge storage regions of a plurality of memory cells of the nonvolatile memory device;
after performing the erase operation, performing, based on applying a back-tunneling voltage to a target wordline and a boosting voltage greater than the back-tunneling voltage to a neighboring wordline adjacent to the target wordline, back-tunneling electron-injection operation to inject a second set of electrons of the electrons into a spacer region between (i) a first charge storage region of the plurality of charge storage regions that corresponds to the target wordline and (ii) a second charge storage region of the plurality of charge storage regions that corresponds to the neighboring wordline; and
after performing the back-tunneling electron-injection operation, performing a program operation to inject a third set of electrons of the electrons into the first charge storage region.

2. The method of claim 1, further comprising:
floating a channel of the plurality of memory cells while the back-tunneling electron-injection operation is being performed.

3. The method of claim 2, wherein, while the back-tunneling electron-injection operation is being performed, a first portion of the channel corresponding to the target wordline is boosted to the back-tunneling voltage and a second portion of the channel corresponding to the neighboring wordline is boosted to the boosting voltage.

4. The method of claim 3, wherein, while the back-tunneling electron-injection operation is being performed, an electric field is formed in a diagonal direction from the second portion of the channel to the target wordline, and the second set of electrons are injected from the target wordline to the spacer region based on the electric field.

5. The method of claim 1, wherein the erase operation and the program operation are performed based on front-tunneling such that respective electrons of the first set and the third set of electrons migrate into a tunneling insulation layer between the plurality of charge storage regions and a channel of the plurality of memory cells, and
wherein the back-tunneling electron-injection operation is performed based on back-tunneling such that the second set of electrons migrate into a blocking insulation layer between the spacer region and the target wordline.

6. The method of claim 1, wherein performing the back-tunneling electron-injection operation comprises:
applying the boosting voltage to the target wordline and the neighboring wordline during a first operation period;
maintaining the boosting voltage applied to the neighboring wordline during a second operation period after the first operation period; and
applying the back-tunneling voltage to the target wordline during the second operation period.

7. The method of claim 1, wherein the boosting voltage has a positive voltage level, and the back-tunneling voltage has a negative voltage level.

8. The method of claim 1, wherein the boosting voltage has a voltage level between 5V and 15V, and the back-tunneling voltage has a voltage level between -5V and 3V.

9. The method of claim 1, wherein performing the back-tunneling electron-injection operation comprises:
while a channel of the plurality of memory cells is floated, applying the boosting voltage to even-numbered wordlines among a plurality of wordlines respectively connected to the plurality of memory cells; and
while the boosting voltage is being applied to the even-numbered wordlines, applying the back-tunneling voltage to odd-numbered wordlines among the plurality of wordlines.

10. The method of claim 1, wherein performing the back-tunneling electron-injection operation comprises:
while a channel of the plurality of memory cells is floated, applying the boosting voltage to odd-numbered wordlines among a plurality of wordlines respectively connected to the plurality of memory cells; and
while the boosting voltage is being applied to the odd-numbered wordlines, applying the back-tunneling voltage to even-numbered wordlines among the plurality of wordlines.

11. The method of claim 1, wherein performing the back-tunneling electron-injection operation comprises:
applying the boosting voltage to even-numbered wordlines among a plurality of wordlines respectively connected to the plurality of memory cells;
while the boosting voltage is being applied to the even-numbered wordlines, applying the back-tunneling voltage to odd-numbered wordlines among the plurality of wordlines;
applying the boosting voltage to the odd-numbered wordlines; and
while the boosting voltage is being applied to the odd-numbered wordlines, applying the back-tunneling voltage to the even-numbered wordlines.

12. The method of claim 1, wherein the plurality of memory cells are in a channel hole such that a cross-sectional area of the channel hole decreases gradually toward a semiconductor substrate, and a difference between the boosting voltage and the back-tunneling voltage increases as the cross-sectional area of the channel holes decreases.

13. The method of claim 12, wherein a plurality of wordlines respectively connected to the plurality of memory cells are grouped into a plurality of wordline groups based on the cross-sectional area of the channel hole, and
wherein the difference between the boosting voltage and the back-tunneling voltage is determined per wordline group of the plurality of wordline groups.

14. A nonvolatile memory device, comprising:
a memory cell array comprising a plurality of memory cells; and
a plurality of peripheral circuits configured to:
perform an erase operation to release a first set of electrons at a plurality of charge storage regions of the plurality of memory cells of the nonvolatile memory device;
after performing the erase operation, perform, based on applying a back-tunneling voltage to a target wordline and a boosting voltage greater than the back-tunneling voltage to a neighboring wordline adjacent to the target wordline, a back-tunneling electron-injection operation to inject a second set of electrons into a spacer region between (i) a first charge storage region of the plurality of storage regions that corresponds to the target wordline and (ii) a second charge storage region of the plurality of storage regions that corresponds to the neighboring wordline; and
after performing the back-tunneling electron-injection operation, perform a program operation to inject electrons into the first charge storage region.

15. The nonvolatile memory device of claim 14, wherein the plurality of peripheral circuits are configured to float a channel of the plurality of memory cells while the back-tunneling electron-injection operation is being performed.

16. The nonvolatile memory device of claim 14, wherein the plurality of peripheral circuits are configured to:
perform the erase operation and the program operation based on front-tunneling such that respective electrons of the first set and the second set of electrons migrate into a tunneling insulation layer between the plurality of charge storage regions and a channel of the plurality of memory cells, and
perform the back-tunneling electron-injection operation based on back-tunneling such that the second set of electrons migrate into a blocking insulation layer between the spacer region and the target wordline.

17. The nonvolatile memory device of claim 14, wherein the plurality of peripheral circuits are configured to, during the back-tunneling electron-injection operation:
apply the boosting voltage to the target wordline and the neighboring wordline during a first operation period;
maintain the boosting voltage applied to the neighboring wordline during a second operation period after the first operation period; and
apply the back-tunneling voltage to the target wordline during the second operation period.

18. The nonvolatile memory device of claim 14, wherein the boosting voltage has a positive voltage level, and the back-tunneling voltage has a negative voltage level.

19. The nonvolatile memory device of claim 14, wherein the peripheral circuits are configured to, during the back-tunneling electron-injection operation:
while a channel of the plurality of memory cells is floated, apply the boosting voltage to odd-numbered wordlines among a plurality of wordlines respectively connected to the plurality of memory cells; and
while the boosting voltage is being applied to the odd-numbered wordlines, apply the back-tunneling voltage to even-numbered wordlines among the plurality of wordlines.

20. A nonvolatile memory device comprising:
a plurality of first metal pads at a cell region;
a plurality of second metal pads at a peripheral region below the cell region, the peripheral region being vertically connected to the cell region based on the plurality of first metal pads and the plurality of second metal pads;
a memory cell array in the cell region and comprising a plurality of memory cells; and
a plurality of peripheral circuits at the peripheral region,
wherein the plurality of peripheral circuits are configured to:
perform an erase operation to release a first set of electrons at a plurality of charge storage regions of the plurality of memory cells of the nonvolatile memory device,
after performing the erase operation, perform, based on applying a back-tunneling voltage to a target wordline and a boosting voltage greater than the back-tunneling voltage to a neighboring wordline adjacent to the target wordline, back-tunneling electron-injection operation to inject a second set of electrons of the electrons into a spacer region between (i) a first charge storage region of the plurality of charge storage regions that corresponds to the target wordline and (ii) a second charge storage region of the plurality of charge storage regions that corresponds to the neighboring wordline, and
after performing the back-tunneling electron-injection operation, perform a program operation to inject electrons into the first charge storage region.
